(19) United States
(12) Patent Application Publication
(10) Pub. No.: US 2018/0027662 A1
(43) Pub. Date: Jan. 25, 2018

(54) SCREEN EXTENDING FRAME

(71) Applicant: Furetsu KASUYA, Tokyo (JP)

(72) Inventor: Furetsu KASUYA, Tokyo (JP)

(21) Appl. No.: 15/664,574

(22) Filed: Jul. 31, 2017

Related U.S. Application Data
(62) Division of application No. 13/522,606, filed on Jul. 31, 2012, now abandoned.

(30) Foreign Application Priority Data
Jan. 29, 2010 (JP) 2010-018703
Jan. 29, 2010 (JP) 2010-018704

(51) Int. Cl. H05K 3/12; B41F 15/36; H05K 3/34

(52) U.S. Cl. CPC H05K 3/1225; B41F 15/36; H05K 3/3484

(57) ABSTRACT

A screen extending frame including cut grooves formed from an inner side to an outer side thereof, or from the outer side to the inner side, or in both directions of joints of the screen extending frame, which is constituted by connecting four frame members in a rectangle shape. The cut grooves enable the joints to deform. The four frame members are individual bodies that are joined by corner members, and connecting portions are inclined with respect to the longitudinal direction of the frame members. Gaps are created in the connections. Elastic elements can be placed at the connections of the four frame members. Alternatively, the joint portions are orthogonal to the longitudinal direction, and elastic elements are placed at the joints.

This application is a divisional of application Ser. No. 13/522,606, which is the National Stage of International Application No. PCT/JP2011/051722, filed Jan. 28, 2011.

### BACKGROUND OF THE INVENTION

### 1. Technical Field

The present invention relates to a screen extending frame in which a screen for screen printing in a sheet shape or a mesh shape is extended and is mounted on a screen extending jig for adjusting tension of the screen in regard to manufacturing of printed circuit boards.

### 2. Description of the Related Art

A printed circuit board in the subtractive process that is generally used in electric/electronic devices is configured to be formed with a conductive pattern by removing unnecessary portions of copper foil stuck to an insulating substrate, and active and passive elements are fixed to the conductive pattern by means of soldering, or the like.

In the subtractive process, after holes are made on an insulating substrate, such as a glass epoxy plate, to which copper foil is stuck, unnecessary portions of the copper foil is removed by printing and etching, and then a conductive pattern is formed. When soldering is performed by a reflow method, solder cream is printed further on necessary portions.

In screen printing, a screen board, which is a mesh-like sheet woven with a metal or a resin or a sheet made of a metal or a resin, is used by forming holes of image thereon and by extending the sheet in a frame with uniform tension, not making crinkles.

With regard to a printed pattern, a metal mask where through holes are formed on a metal thin plate made of stainless steel or the like is extended in a screen extending frame with tension, ink is transferred onto the insulating substrate via the through holes using a squeegee, and thereby, a conductive pattern or a solder pattern is formed thereon.

At this moment, if the screen board does not come into tight contact with the object to be printed, the ink runs over from a gap causing bleeding, which results in inaccurate printing.

A planar shape is ideal for the object to be printed, but there may be warping or waviness thereon in some cases, and a material with flexibility is selected for the squeegee in order to keep the screen board in tight contact with the printed object, and the extending tension of the screen is not so tensed.

However, since the screen is required to be as strongly extended as possible, a rigid and sturdy screen frame is prepared, the sheet is intensively pulled from four directions, and extended using a stretching property of the sheet material and using a repulsive force thereof.

When a metal mesh is used, it can be extended since the mesh does not have a high stretching property but has a little. When a metal sheet with no stretching property is used, the sheet can be extended by connecting the outer circumference of the centered metal sheet to a resin sheet having the stretching property.

The screen is used as attached to the screen extending frame. If there has slack, the location of the printed pattern is deviated or the pattern is warped when the screen is rubbed by the squeegee. In order to prevent such a situation, it is necessary to always give a certain degree of tension to the screen by exerting a tensile force thereto when printing is performed.

For a screen extending frame, there are a tension fixed frame of which the size is fixed so as to maintain the tensile force of the screen constant, and a tension variable frame of which the size varies so as to be able to change the tensile force of the screen. Since both frames are required to have strength that gives a tensile force to the screen, the frames have to be robust and large. In addition, the tension variable frame of which the size varies includes a variable mechanism, and accordingly, the frame costs higher.

The screen needs to be separated from the circuit board to be printed before and after printing, and to be brought into tight contact with the circuit board when printing is performed using a squeegee. For this reason, the screen is required to have the stretching property. However, since the metal mask does not have the stretching property, it is, in general, stuck to a mesh made of polyester strings, stainless steel strings, or the like and is used as a screen. There may be a case where a metal mask is used as it is, and in that case, any extending and reducing mechanism is provided in the mounting portion of the metal mask or in the screen extending frame.

A screen using a mesh is attached to the screen extending frame mostly by using an adhesive agent, and such the screen is kept attached to the screen extending frame so long as the screen is necessary. For this reason, when being not in use, the heavy and bulky screen has to be stored or transported.

There is a screen extending frame in a configuration where the end part of the screen using a mesh is attached thereto by means of winding, clamping, or the like. In a case of such the screen extending frame, it is possible to remove the screen from the screen extending frame for storage or transportation when the screen is not in use, but it is not easy to store or transport the screen without damaging the printing patterns that are precisely formed thereon as the screen is thin.

Taking the circumstances into consideration, the present inventor has proposed in Patent Application No. 2002-556010 (refer to Publication No. WO2002/055304) a device for screen printing in which a screen extending frame is divided into a screen extending jig having a tensile force adjusting mechanism and a screen extending frame in a simple structure without the tensile force adjusting mechanism, which is provided with an engagement mechanism to connect the jig and the frame with each other, and thereby, the screen is attached to the screen extending frame.

The screen printing device is described referring to FIG. 1.

In FIG. 1(A), the reference numeral 1 is the screen extending jig, and the screen extending frame 2 having engagement grooves 4 is mounted on the screen extending jig 1. To the screen extending frame 2, a screen 3 is attached, which is a sheet that is a metal plate or a resin plate with conductive patterns formed by through holes, or is a mesh stuck a sheet with conductive patterns formed by through holes, not shown in the drawing, thereto. By extending and reducing the screen extending jig 1, an appropriate tensile force is exerted on the screen 3.

The screen extending frame 2 is constituted by joining four plate-shaped, or rectangular tube-shaped frame members together by means of welding, or the like.

In description hereinafter, on frame members constituting the screen extending frame, the length in the longitudinal direction of each frame member represents the “length”, the length from the outside to the inside thereof represents the “width”, and the length between a face to which the sheet is attached and a face to which the sheet is not attached represents the “thickness”.

FIGS. 1(B) and (C) illustrate mounting the screen extending frame 2 on the screen extending jig 1. FIG. 1(B) shows the state of the screen extending frame 2 before being mounted on the screen extending jig 1, and FIG. 1(C) shows the state of the screen extending frame 2 being mounted on the screen extending jig 1.

The engagement grooves 4 are formed on the mounting sides of the screen extending frame 2 along the longitudinal direction of the screen extending jig, and engagement elements 5 are formed on the mounting sides of the screen extending jig 1 along the longitudinal direction of the screen extending jig.

The tensile force to the screen 3 is adjusted by extending or reducing the screen extending jig 1 in the arrow directions shown in the drawing where the engagement elements 5 are kept engaged with the engagement grooves 4.

Conductive patterns are formed using the screen by transferring ink with a squeegee not shown in the drawing via through holes.

When the screen is not in use and to be stored, it is most ideal to store the screen extending frame 2 being mounted on the screen extending jig 1, but since the screen extending jig 1 having an extending and reducing mechanism is not only expensive but also bulky, storage or transportation of the screen extending frame 2 attached with the screen being mounted on the screen extending jig 1 is not efficient.

The screen is attached to the screen extending frame 2 by fixing means such as an adhesive agent, that is mounted on the screen extending jig 1, and the tensile force is exerted thereon by the screen extending jig 1. When not being mounted on the screen extending jig 1, slack or the like occurs which may cause the screen deformation. It is, therefore, desirable for the screen to have a certain degree of tension even being attached only to the screen extending frame 2.

A screen printing device using a screen extending frame, in which the screen is attached to a screen extending frame, the screen extending frame is mounted on the screen extending jig, and the tension of the screen is adjusted by changing the size of the screen extending jig, is disclosed in Japanese Patent Laid-Open Publication Nos. 2006-212955, 2006-44180 and 2008-1010 by the present inventor, in addition to the publication WO2002/055304. Furthermore, Japanese Patent Laid-Open Publication No. 2000-15777 also describes a screen printing device using a screen extending frame.

### RELATED ART REFERENCES

Document 1: JP-A-2000-15777

Document 2: WO2002/055304

Document 3: JP-A-2006-44180

### SUMMARY OF THE INVENTION

These screen extending frames of the prior art can exert a certain degree of tension on the screen by exerting the tensile force to the screen when the screen is fixed thereto, but since the frame has no function of exerting the tensile force, it is not possible to exert a sufficient tension. For this reason, if the screen extending frame is removed from the bulky screen extending jig in order to effectively use the expensive screen extending frame to save space for storage and transportation, there is a concern that slack occurs in the screen, resulting in deformation of the screen.

The invention according to the present application aims to provide a screen extending frame that can prevent the above circumstance.

The configuration overview of the invention for achieving the above aim is as follows.

According to the invention provided in the present application, cut grooves are formed in the inner sides and/or outer sides of connections orthogonally connecting four frame members constituting a screen extending frame so that the angles of the connections change, allowing the frame members inwardly or outwardly change in shape, and accordingly, the size of the screen extending frame variable.

The screen extending frame mounted with an elastic element is reduced by a jig such as a screen extending jig having an extending and reducing function, a screen is attached to the screen extending frame in that state, and when fixing work, such as adhesion, is completed, setting the extending or reducing degree of the screen extending jig to be optimum, then screen printing is performed.

It is possible to extend and reduce the screen extending frame with an extending function by setting the function of extending the screen extending frame in a screen printing device.

In addition, in order to achieve the object of the invention, a gap or an elastic element is provided in each joint of the four frame members so as to give an extending force to an end of a frame side in each connections of the frame members, whereby flexibility is given to the extending frame, according to the invention of the present application.

For the elastic element to be provided, a solid elastic element such as natural rubber or synthetic rubber, or a non-solid spring such as a plate spring or a coil spring can be used, and it is also possible to further provide an elastic element in the gap in the joint.

The screen extending frame mounted with the elastic element is reduced by a jig such as a screen extending jig having an extending and reducing function, a screen is attached to the screen extending frame in that state, and when fixing work, such as adhesion, is completed, setting the extending or reducing degree of the screen extending jig to be optimum, then screen printing is performed.

It is possible to reduce the screen extending frame with a reducing function by setting the function of reducing the screen extending frame in a screen printing device.

Specific configurations for achieving the above objective are described in the following (1) to (38).

(1) A screen extending frame in a rectangular shape which is constituted by four frame members having the square-shape cross-section, and is used in such a way that a screen is attached to one face thereof, and the other face thereof is mounted on a screen extending jig having an extending and reducing function, in which joint of the four frame members have flexibility and elasticity.

(2) The screen extending frame according to (1) above, in which the four frame members connect in the joint, and the joint have flexibility and elasticity.

(3) The screen extending frame according to (2) above, in which the four frame members are solid bodies.

(4) The screen extending frame according to (3) above, in which cut grooves are formed in the width direction of the joints.

(5) The screen extending frame according to (3) above, in which cut grooves are formed in the direction connecting the outer corner and the inner corner each of the joints.

(6) The screen extending frame according to (3) above, in which grooves are formed on both faces of the joints in the thickness direction.

(7) The screen extending frame according to (6) above, in which the grooves in the thickness direction are formed in the width direction of the frame members.

(8) The screen extending frame according to (6) above, in which the grooves in the thickness direction are formed in the direction connecting the outer corner and the inner corner each of the joints.

### BRIEF DESCRIPTION OF THE DRAWINGS

FIGS. 1(A)-1(C) illustrate a screen extending jig and a screen extending frame of the related art.

FIGS. 2(A)-2(C) are illustrative configuration diagrams of a screen extending frame according to Embodiment 1.

FIG. 3 is an illustrative function diagram of the screen extending frame according to Embodiment 1.

FIGS. 4(A)-4(C) are illustrative configuration diagrams of a screen extending frame according to Embodiment 2.

FIG. 5 is an illustrative function diagram of the screen extending frame according to Embodiment 2.

FIGS. 6(A)-6(C) are illustrative configuration diagrams of a screen extending frame according to Embodiment 3.

FIGS. 7(A)-7(C) are illustrative configuration diagrams of a screen extending frame according to Embodiment 4.

FIGS. 8(A)-8(C) are illustrative configuration diagrams of a screen extending frame according to Embodiment 5.

FIGS. 9(A)-9(C) are illustrative configuration diagrams of a screen extending frame according to Embodiment 6.

FIGS. 10(A)-10(C) are illustrative configuration diagrams of a screen extending frame according to Embodiment 7.

FIGS. 11(A)-11(C) are illustrative configuration diagrams of a screen extending frame according to Embodiment 8.

FIGS. 12 (A)-12(C) are illustrative configuration diagrams of a screen extending frame according to Embodiment 9.

FIGS. 13(A)-13(C) are illustrative configuration diagrams of a screen extending frame according to Embodiment 10.

FIGS. 14(A)-14(C) are illustrative configuration diagrams of a screen extending frame according to Embodiment 11.

FIGS. 15(A)-15(C) are illustrative configuration diagrams of a screen extending frame according to Embodiment 12.

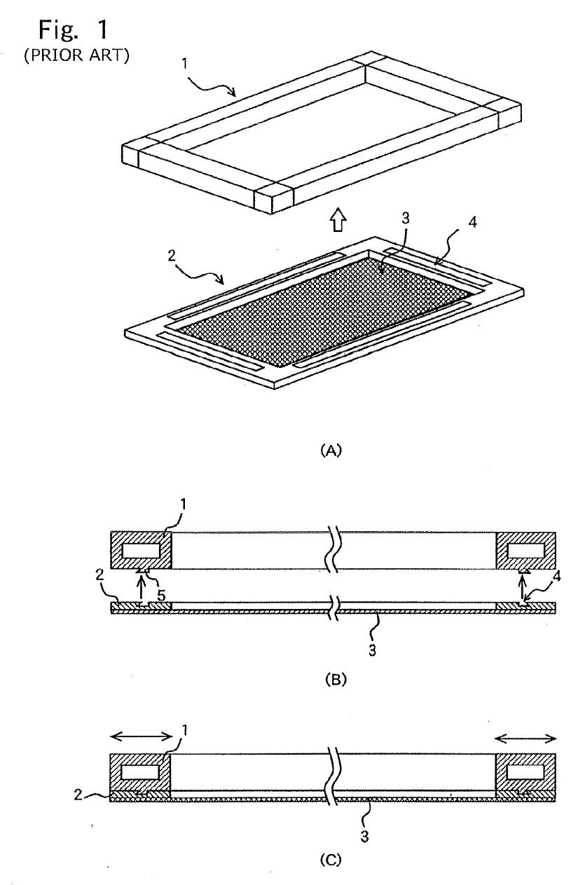

### DETAILED DESCRIPTION OF THE INVENTION

Hereinafter, embodiments of the invention according to the present application are described with reference to the drawings.

A screen extending frame to be shown in embodiments is a screen extending frame in a rectangular shape and used, when a screen is attached thereto, by being mounted on a screen extending jig having an extending and reducing function. It is constituted by a first frame member and a third frame member that are arranged in parallel and have the same length, and a second frame member and a fourth frame member that are arranged in parallel and have the same length, the cross-sections of the first, the second, the third and the fourth frame members are square, one faces of the first, the second, the third and the fourth frame members are plane to which the screen is attached. A rectangular screen extending frame is formed by connecting the first and the second frame members, the second and the third frame members, the third and the fourth frame members, and the fourth and the first frame members, and the corners of the screen extending frame are configured so as to have flexibility and elasticity.

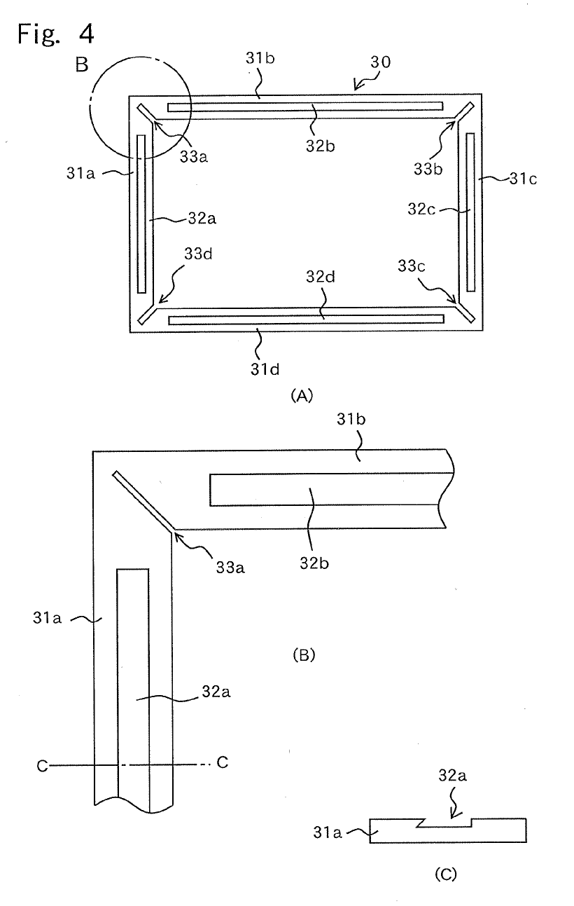

In screen extending frames of Embodiments 1 to 12 shown in FIGS. 4 to 15, four frame members constituting the frame each are formed in a single unit.

In Embodiments 1 to 12 described with reference to FIGS. 4 to 15, flexibility of the joints of the solid screen extending frames is obtained through cut grooves formed in the joints of the frame members in the width direction.

### EMBODIMENT 1

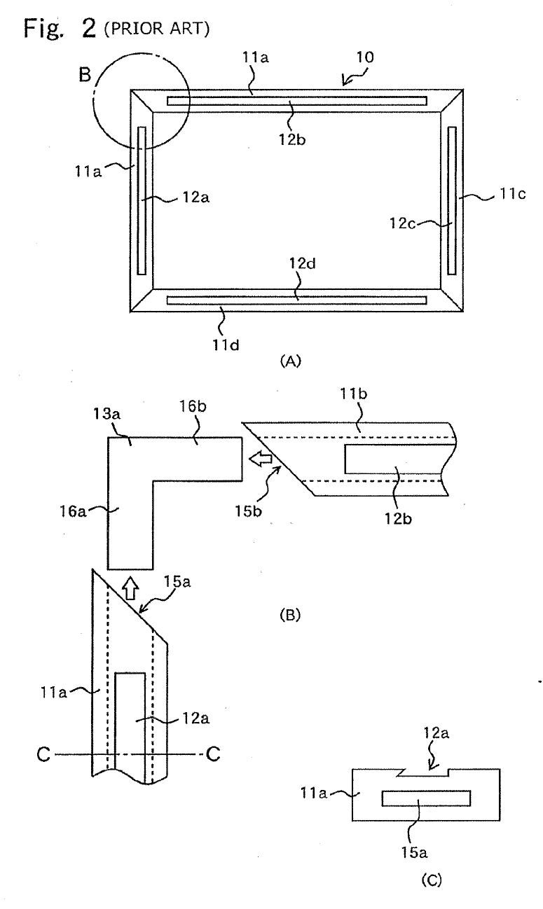

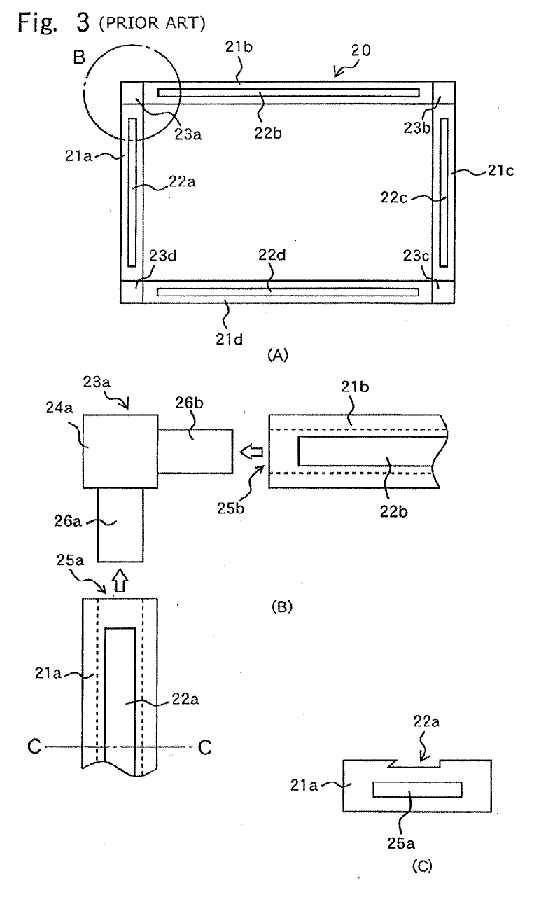

FIG. 2 shows a configuration of Embodiment 1, and FIG. 3 illustrates the function of Embodiment 1.

In FIG. 2, (A) is an overall view of a screen extending frame 30, (B) is an enlarged exploded view of a portion indicated by the dashed circle B in (A), and (C) is a cross-sectional view of the portion indicated by the dashed line C in (B).

As shown in FIG. 2(A) of the overall view and FIG. 2(B) of the enlarged exploded view, the screen extending frame 30 is assembled with four frame members 31a, 31b, 31c, and 31d to be formed in a rectangular shape, and structured by fixedly joined by means of welding, or the like.

On the four frame members 31a, 31b, 31c, and 31d, engagement grooves 32a, 32b, 32c, and 32d with which engagement elements formed in a screen extending jig are engaged each are formed.

A cut groove 33a in the inner side of the joint of the frame members 31a and 31b from the inner corner to the outer corner; a cut groove 33b in the inner side of the joint of the frame members 31b and 31c from the inner corner to the outer corner; a cut groove 33c in the inner side of the joint of the frame members 31c and 31d from the inner corner to the outer corner; and a cut groove 33d in the inner side of the joint of the frame members 31d and 31a from the inner corner to the outer corner are formed.

All of the four frame members 31a, 31b, 31c, and 31d have the same cross-sectional shape, the engagement groove 32a with which an engagement element of the screen extending jig is engaged is formed on one face of the frame member 31a as shown by the cross-section in FIG. 4(C), and the opposite face is set to be a plane in order to attach the screen thereto.

When the screen is attached to the screen extending frame 30, the engagement elements of the extending jig are engaged with the engagement grooves 32a, 32b, 32c, and 32d, and the extending jig is extended and reduced, the screen extending frame 30 extends and reduces, and accordingly, the tensile force to the screen is adjusted.

The function of the screen extending frame 30 is described referring to FIG. 3 The screen extending frame 30 configured by the joined four frame members 31a, 31b, 31c, and 31d is pressed in the directions of the black arrows using a tool such as the screen extending jig, a clamp, a vise, or the like, not shown in the drawing. For this reason, as the open ends of the cut grooves 33a, 33b, 33c, and 33d reduce, the frame members 31a, 31b, 31c, and 31d inwardly bend, and the screen extending frame 10 is reduced, and resulted a reduced screen extending frame 30′ constituted by curved frame members 31a′, 31b′, 31c′, and 31d′.

Then, the screen is fixed to the reduced screen extending frame 30′ by means of adhesion, or the like.

In the state where fixation of the screen to the reduced screen extending frame 30′ is completed, the pressing force to the reduced screen extending frame 30′ exerted by the screen extending jig, the clamp, the vice, or the like is released.

When the pressing force to the reduced screen extending frame 30′ is released, the curved frame members 31a′, 31b′, 31c′, and 31d′ that inwardly bend will return to the shape of the state of not being compressed, and as the open ends of the cut grooves 33a′ 33b′, 33c′, and 33d′ open widely, the reduced screen extending frame 30′ extends, and accordingly, a tensile force is exerted on the screen attached to the screen extending frame thus extended.

Since the tensile force is exerted even in the state of not using the extending jig, it is possible to keep the screen to be in tension even in the state where the screen is simply fixed to the screen extending frame, and there occurs no sagging in the screen.

As is obvious from the above description of the function, the screen extending frame gives a tensile force on the screen even when the extending jig is not used, and therefore, it is possible to perform screen printing only with the screen extending frame alone without using the screen extending jig.

Insertion of a solid elastic element such as natural rubber or synthetic rubber or a non-solid spring such as a plate spring or a coil spring into the cut grooves 33a, 33b, 33c, and 33d enables protection of the open ends and supplementation of elasticity.

### EMBODIMENT 2

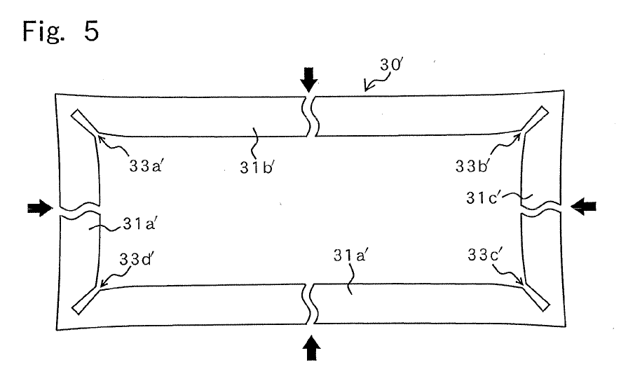

Embodiment 2 obtained by modifying Embodiment 1 is shown in FIG. 4, and the function of Embodiment 2 is described referring to FIG. 5.

In the drawing, (A) is an overall view of a screen extending frame 40, (B) is an enlarged exploded view of a portion indicated by a dashed circle B in (A), and (C) is a cross-sectional view of a portion indicated by a dashed line C in (B).

As shown in FIG. 5(A) of the overall view and FIG. 5(B) of the enlarged exploded view, the screen extending frame 40 is assembled with four frame members 41a, 41b, 41c, and 41d to be formed in a rectangular shape, and structured by fixedly joined by means of welding, or the like.

On the four frame members 41a, 41b, 41c, and 41d, engagement grooves 42a, 42b, 42c, and 42d with which engagement elements formed in screen extending jig are engaged each are formed.

An inclined cut groove 43a in the inner side of the joint of the frame members 41a and 41b from the inner corner to the outer corner; a narrow inclined cut groove 43b in the inner side of the joint of the frame members 41b and 41c from the inner corner to the outer corner; a narrow inclined cut groove 43c in the inner side of the joint of the frame members 41c and 41d from the inner corner to the outer corner; and a narrow inclined cut groove 43d in the inner side of the joint of the frame members 41d and 41a from the inner corner to the outer angle are formed.

Furthermore, there are formed on the frame member 41a a narrow cut groove 44ab from the outer side orthogonally toward the inner side at the joint with the frame member 41b and a narrow cut groove 44ad from the outer side orthogonally toward the inner side at the joint thereof with the frame member 41d; on the frame member 41b a narrow cut groove 44ba from the outer side orthogonally toward the inner side at the joint with the frame member 41a and a narrow cut groove 44bc from the outer side orthogonally toward the inner side at the joint thereof with the frame member 41c; on the frame member 41c a narrow cut groove 44cb from the outer side orthogonally toward the inner side at the joint with the frame member 41b and a narrow cut groove 44cd from the outer side orthogonally toward the inner side at the joint thereof with the frame member 41d; and on the frame member 41d a narrow cut groove 44dc from the outer side orthogonally toward the inner side at the joint with the frame member 41c and a narrow cut groove 44da from the outer side orthogonally toward the inner side at the joint thereof with the frame member 41a.

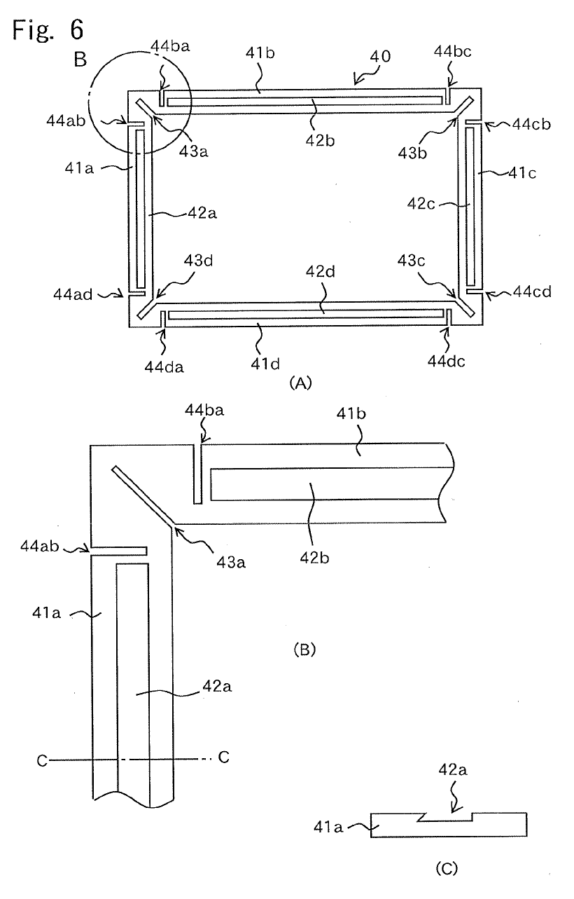

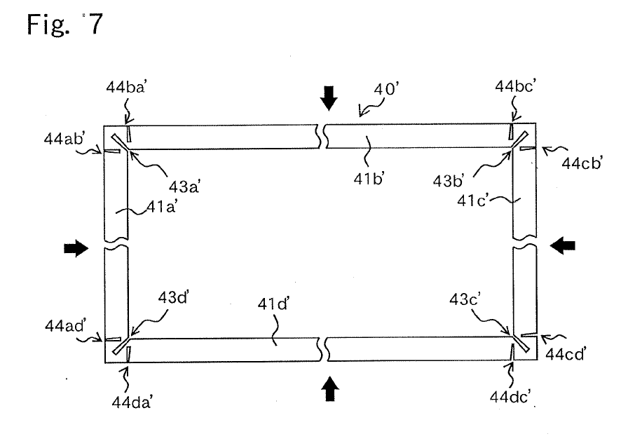

All of the four frame members 41a, 41b, 41c, and 41d have the same cross-sectional shape, the engagement groove 42a with which an engagement element of the screen extending jig is engaged is formed on one face of the frame member 41a as shown by the cross-section in FIG. 6(C), and the opposite face is set to be a plane in order to attach the screen thereto.

When the screen is attached to the screen extending frame 40, the engagement elements of the extending jig are engaged with the engagement grooves 42a, 42b, 42c, and 42d, and the extending jig is extended and reduced, the screen extending frame 40 extends and reduces, and accordingly, the tensile force to the screen is adjusted.

The function of the screen extending frame 40 is described referring to FIG. 5. In the drawing, the screen extending frame 40 configured by the joined four frame members 41a, 41b, 41c, and 41d is pressed in the directions of the black arrows using a tool such as the screen extending jig, a clamp, a vise, or the like, not shown in the drawing. For this reason, as the open ends of the cut grooves 43a, 43b, 43c, and 43d are reduced, resulting in reduced open ends 43a′, 43b′, 43c′, 43d′, 43ab′, 43ba′, 43bc′, 43cb′, 43cd′, 43dc′, 43da′, and 43ad′, the frame members 41a, 41b, 41c, and 41d inwardly shift, causing the screen extending frame 40 to be reduced, and resulted a reduced screen extending frame 40′ constituted by reduced frame members 41a′, 41b′, 41c′, and 41d′.

The screen is, then, fixed to the screen extending frame 40′ by means of adhesion, or the like.

In the state where fixation of the screen to the reduced screen extending frame 40′ is completed, the pressing force to the reduced screen extending frame 40′ exerted by the screen extending jig, the clamp, the vice, or the like is released.

When the pressing force to the reduced screen extending frame 40′ is released, the frame members 41a′, 41b′, 41c′, and 41d′ that inwardly shift will return to the shape of the state not being compressed, and as the open ends of the cut grooves 43a′, 43b′, 43c′, 43d′, 43ab′, 43ba′, 43bc′, 43cb′, 43cd′, 43dc′, 43da′, and 43ad′ open widely, the reduced screen extending frame 40′ extends, and a tensile force is exerted on the screen fixed to the screen extending frame thus extended.

Since the tensile force is exerted even in the state of not using the extending jig, it is possible to keep the screen to be in tension even in the state where the screen is simply fixed to the screen extending frame, and there occurs no sagging in the screen.

As is obvious from the above description of the function, the screen extending frame gives the tensile force on the screen even when the extending jig is not used, and therefore, it is possible to perform screen printing only with the screen extending frame alone without using the screen extending jig.

Insertion of a solid elastic element such as natural rubber or synthetic rubber or a non-solid spring such as a plate spring or a coil spring into the cut grooves 43a, 43b, 43c, 43d, 43ab, 43ba, 43bc, 43cb, 43cd, 43dc, 43da, and 43ad enables protection of the open ends and supplementation of elasticity.

### EMBODIMENT 3

Embodiment 3 that is another Embodiment obtained by modifying Embodiment 1 is shown in FIG. 6.

In the drawing, (A) is an overall view of a screen extending frame 50, (B) is an enlarged exploded view of a portion indicated by a dashed circle B in (A), and (C) is a cross-sectional view of a portion indicated by a dashed line C in (B).

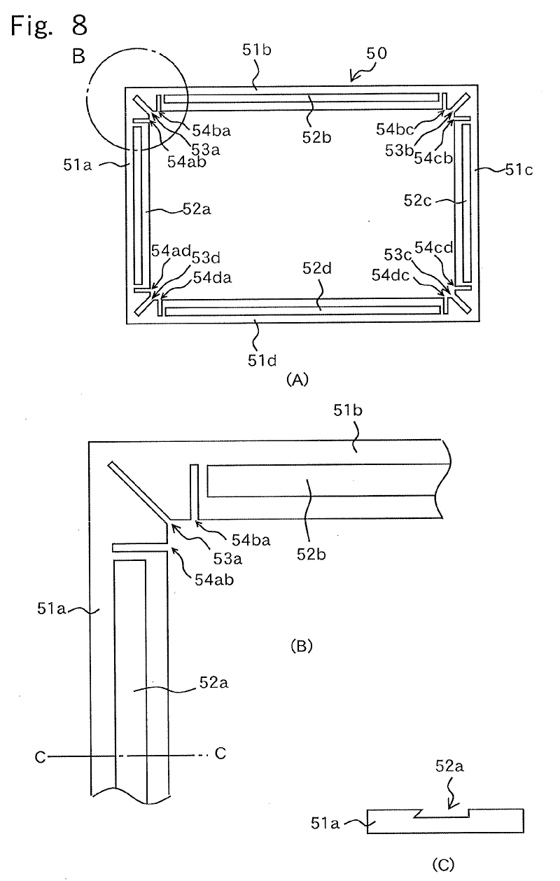

As shown in FIG. 8(A) of the overall view and FIG. 8(B) of the enlarged exploded view, the screen extending frame 50 is assembled with four frame members 51a, 51b, 51c, and 51d to be formed in a rectangular shape, and structured by fixedly joined by means of welding, or the like.

On the four frame members 51a, 51b, 51c, and 51d, engagement grooves 52a, 52b, 52c, and 52d with which engagement elements formed in a screen extending jig are engaged each are formed.

There are formed a narrow inclined cut groove 53a in the inner side of the joint of the frame members 51a and 51b from the inner corner to the outer corner; a narrow inclined cut groove 53b in the inner side of the joint of the frame members 51b and 51c from the inner corner to the outer corner; a narrow inclined cut groove 53c in the inner side of the joint of the frame members 51c and 51d from the inner corner to the outer corner; and a narrow inclined cut groove 53d in the inner side of the joint of the frame members 51d and 51a from the inner angle to the outer angle.

Furthermore, there are formed on the frame member 51a a cut groove 54ab that is orthogonal to the outer side from the inner side of the joint with the frame member 51b and a narrow cut groove 54ad that is orthogonal to the outer side from the inner side of the joint thereof with the frame member 51d; on the frame member 51b a narrow cut groove 54ba that is orthogonal to the outer side from the inner side of the joint with the frame member 51a and a narrow cut groove 54bc that is orthogonal to the outer side from the inner side of the joint thereof with the frame member 51c; on the frame member 51c a narrow cut groove 54cb that is orthogonal to the outer side from the inner side of the joint with the frame member 51b and a narrow cut groove 54cd that is orthogonal to the outer side from the inner side of the joint thereof with the frame member 51d; and on the frame member 51d a narrow cut groove 54dc that is orthogonal to the outer side from the inner side of the joint with the frame member 51c and a narrow cut groove 54da that is orthogonal to the outer side from the inner side of the joint thereof with the frame member 51a.

All of the four frame members 51a, 51b, 51c, and 51d have the same cross-sectional shape, the engagement groove 52a with which an engagement element of the screen extending jig is engaged is formed on one face of the frame member 51a as shown by the cross-section in FIG. 8(C), and the opposite face is set to be a plane in order to attach the screen thereto.

When the screen is attached to the screen extending frame 50, the engagement elements of the extending jig are engaged with the engagement grooves 52a, 52b, 52c, and 52d, and the extending jig is extended and reduced, the screen extending frame 50 extends and reduces, and accordingly, the tensile force to the screen is adjusted.

When the screen extending frame 50 configured by combining the four frame members 51a, 51b, 51c, and 51d is pressed in the inward direction using a tool such as the screen extending jig, a clamp, a vise, or the like, the open ends of the cut grooves 53a, 54ab, 54ba, 53b, 54bc, 54cb, 53c, 54cd, 54dc, 53d, 54da, and 54ad that are formed inner side are reduced, the frame members 51a, 51b, 51c, and 51d inwardly bend, and accordingly, the screen extending frame 50 is reduced.

The screen is, then, fixed to the screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will return to the shape of the state not being compressed, and as the open ends of the cut grooves 53a, 54ab, 54ba, 53b, 54bc, 54cb, 53c, 54cd, 54dc, 53d, 54da, and 54ad open widely, thereby the frame members 51a, 51b, 51c, and 51d outwardly extend, causing the screen extending frame 50 to extend, and a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 53a, 53b, 53c, 53d, 54ab, 54ba, 54bc, 54cb, 54cd, 54dc, 54da, and 54ad enables protection of the open ends and supplementation of elasticity.

### EMBODIMENT 4

Embodiment 4 that is another Embodiment obtained by modifying Embodiment 1 is shown in FIG. 7.

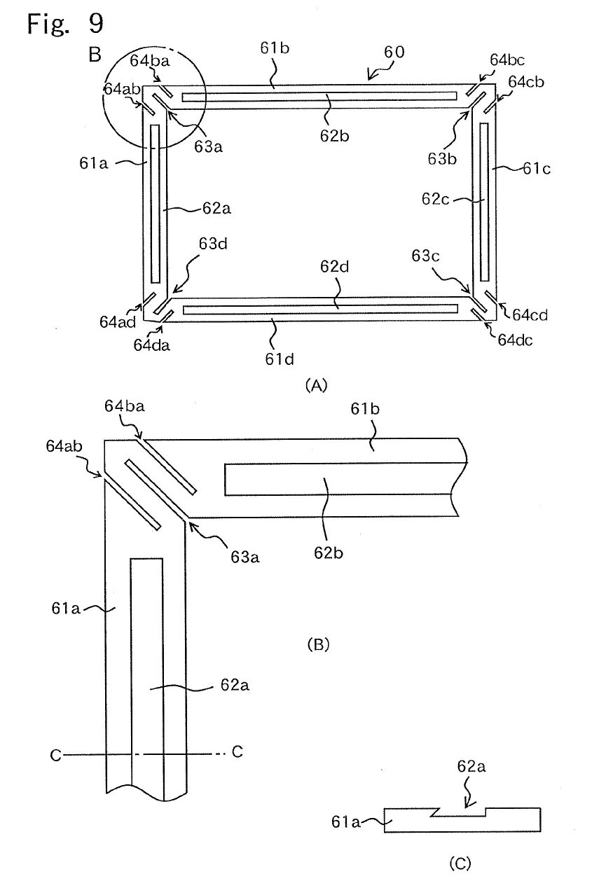

Description of the function corresponding to that of FIG. 3 or FIG. 5 is omitted. In FIG. 9, (A) is an overall view of a screen extending frame 60, (B) is an enlarged exploded view of a portion indicated by a dashed circle B in (A), and (C) is a cross-sectional view of a portion indicated by a dashed line C in (B).

As shown in FIG. 9(A) of the overall view and FIG. 9(B) of the enlarged exploded view, the screen extending frame 60 is assembled with four frame members 61a, 61b, 61c, and 61d to be formed in a rectangular shape, and structured by fixedly joined by means of welding, or the like.

On the four frame members 61a, 61b, 61c, and 61d, engagement grooves 62a, 62b, 62c, and 62d with which engagement elements formed in a screen extending jig are engaged each are formed.

There are formed a narrow inclined cut groove 63a in the outer side of the joint of the frame members 61a and 61b from the outer corner to the inner corner; a narrow inclined cut groove 63b in the outer side of the joint of the frame members 61b and 61c from the outer corner to the inner corner; a narrow inclined cut groove 63c in the outer side of the joint of the frame members 61c and 61d from the outer corner to the inner corner; and a narrow inclined cut groove 63d in the outer side of the joint of the frame members 61d and 61a from the outer corner to the inner corner.

Furthermore, there are formed on the frame member 61a a narrow inclined cut groove 64ab from the outer side toward the inner side of the joint with the frame member 61b and a narrow inclined cut groove 64ad from the outer side toward the inner side of the joint thereof with the frame member 61d; on the frame member 61b a narrow inclined cut groove 64ba from the outer side toward the inner side of the joint with the frame member 61a and a narrow inclined cut groove 64bc from the outer side toward the inner side of the joint thereof with the frame member 61c; on the frame member 61c a narrow inclined cut groove 64cb from the outer side toward the inner side of the joint with the frame member 61b and a narrow inclined cut groove 64cd from the outer side toward the inner side of the joint thereof with the frame member 61d; and on the frame member 61d a narrow inclined cut groove 64dc from the outer side toward the inner side of the joint with the frame member 61c and a narrow inclined cut groove 64da from the outer side toward the inner side of the joint thereof with the frame member 61a.

All of the four frame members 61a, 61b, 61c, and 61d have the same cross-sectional shape, the engagement groove 62a with which an engagement element of the screen extending jig is engaged is formed on one face of the frame member 61a as shown by the cross-section in FIG. 9(C), and the opposite face is set to be a plane in order to attach the screen thereto.

When the screen is attached to the screen extending frame 60, the engagement elements of the extending jig are engaged with the engagement grooves 62a, 62b, 62c, and 62d, and the extending jig is extended and reduced, the screen extending frame 60 extends and reduces, and accordingly, the tensile force to the screen is adjusted.

When the screen extending frame 60 configured by combining the four frame members 61a, 61b, 61c, and 61d is pressed in the inward direction using a tool such as the screen extending jig, a clamp, a vise, or the like, the open ends of the cut grooves 63a, 63b, 63c, and 63d that are formed in the inner side are reduced, the open ends of the cut grooves 64ab, 64ba, 64bc, 64cb, 64cd, 64dc, 64da, and 64ad that are formed in the outer side open widely, and accordingly, the frame members 61a, 61b, 61c, and 61d inwardly bend, causing the screen extending frame 60 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 63a, 63b, 63c, and 63d that are formed in the inner side are widely open and the open ends of the cut grooves 44ab, 64ba, 64bc, 64cb, 64cd, 64dc, 64da, and 64ad that are formed in the outer side are reduced, thereby the frame members 61a, 61b, 61c, and 61d extend to the outer side to extend the screen extending frame 60, and therefore, a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 63a, 63b, 63c, 63d, 64ab, 64ba, 64bc, 64cb, 64cd, 64dc, 64da, and 64ad enables protection of the open ends and supplementation of elasticity.

### EMBODIMENT 5

Embodiment 5 that is another example obtained by modifying Embodiment 1 is shown in FIG. 8.

Description of the function corresponding to that of FIG. 3 or FIG. 5 is omitted. In FIG. 8, (A) is an overall view of a screen extending frame 70, (B) is an enlarged exploded view of a portion indicated by a dashed circle B in (A), and (C) is a cross-sectional view of a portion indicated by a dashed line C in (B).

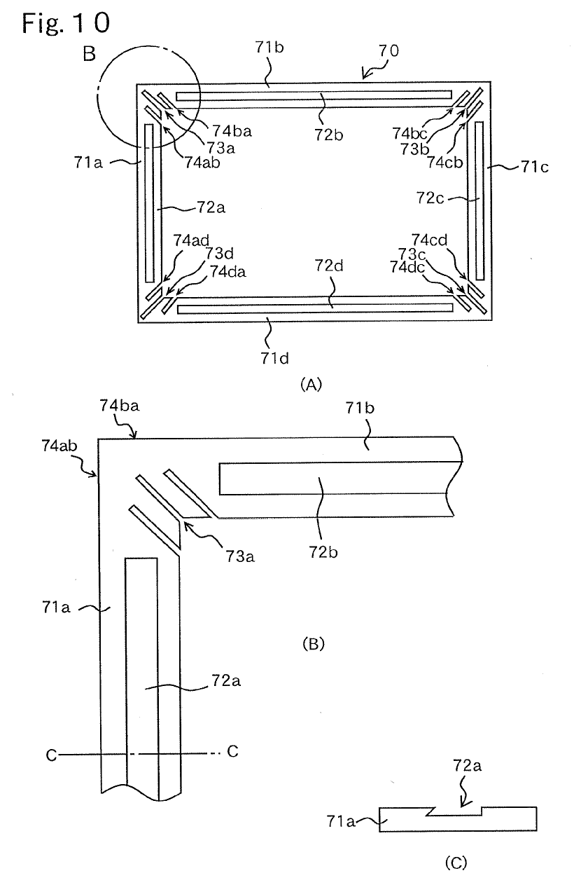

As shown in FIG. 10(A) of the overall view and FIG. 10(B) of the enlarged exploded view, the screen extending frame 70 is assembled with four frame members 71a, 71b, 71c, and 71d to be formed in a rectangular shape, and structured by fixedly joined by means of welding, or the like.

On the four frame members 71a, 71b, 71c, and 71d, engagement grooves 72a, 72b, 72c, and 72d with which engagement elements formed in a screen extending jig are engaged each are formed.

There are formed a narrow inclined cut groove 73 a in the outer side of the joint of the frame members 71a and 71b from the outer corner to the inner corner; a narrow inclined cut groove 73b in the outer side of the joint of the frame members 71b and 71c from the outer corner to the inner corner; a narrow inclined cut groove 73c in the outer side of the joint of the frame members 71c and 71d from the outer corner to the inner corner; and a narrow inclined cut groove 73d in the outer side of the joint of the frame members 71d and 71a from the outer corner to the inner corner.

Furthermore, there are formed on the frame member 71a a narrow inclined cut groove 74ab from the inner side toward the outer side of the joint with the frame member 71b and a narrow inclined cut groove 74ad from the inner side toward the outer side of the joint thereof with the frame member 71d; on the frame member 71b a narrow inclined cut groove 74ba from the inner side toward the outer side of the joint with the frame member 71a and a narrow inclined cut groove 74bc from the inner side toward the outer side of the joint thereof with the frame member 71c; on the frame member 71c a narrow inclined cut groove 74cb from the inner side toward the outer side of the joint with the frame member 71b and a narrow inclined cut groove 74cd from the inner side toward the outer side of the joint thereof with the frame member 71d; and on the frame member 71d a narrow inclined cut groove 74dc from the inner side toward the outer side of the joint with the frame member 71c and a narrow inclined cut groove 74da from the inner side toward the outer side of the joint thereof with the frame member 71a.

All of the four frame members 71a, 71b, 71c, and 71d have the same cross-sectional shape, the engagement groove 72a with which an engagement element of the screen extending jig is engaged is formed on one face of the frame member 71a as shown by the cross-section in FIG. 10(C), and the opposite face is set to be a plane in order to attach the screen thereto.

When the screen is attached to the screen extending frame 70, the engagement elements of the extending jig are engaged with the engagement grooves 72a, 72b, 72c, and 72d, and the extending jig is extended and reduced, the screen extending frame 70 extends and reduces, and accordingly, the tensile force to the screen is adjusted.

When the screen extending frame 70 configured by combining the four frame members 71a, 71b, 71c, and 71d is pressed in the inward direction using a tool such as the screen extending jig, a clamp, a vise, or the like, the open ends of the cut grooves 73a, 73b, 73c, 73d, 74ab, 74ba, 74bc, 74cb, 74cd, 74dc, 74da, and 74ad are reduced, and accordingly, the frame members 71a, 71b, 71c, and 71d inwardly bend, causing the screen extending frame 70 to be reduced.

The screen is, then, fixed to the reduced screen extending frame by means of adhesion, or the like.

the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 73a, 73b, 73c, 73d, 74ab, 74ba, 74bc, 74cb, 74cd, 74dc, 74da, and 74ad are widely open, the frame members 71a, 71b, 71c, and 71d extend to the outer side to extend the screen extending frame 70, and therefore, a tensile force is exerted on the screen attached to the screen extending frame thus extended.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 73a, 73b, 73c, 73d, 74ab, 74ba, 74bc, 74cb, 74cd, 74dc, 74da, and 74ad enables protection of the open ends and supplementation of elasticity.

### EMBODIMENT 6

The configuration of Embodiment 6 is shown in FIG. 9. Description of the function corresponding to that of FIG. 3 or FIG. 5 is omitted. In FIG. 8, (A) is an overall view of a screen extending frame 80, (B) is an enlarged exploded view of a portion indicated by a dashed circle B in (A), and (C) is a cross-sectional view of a portion indicated by a dashed line C in (B).

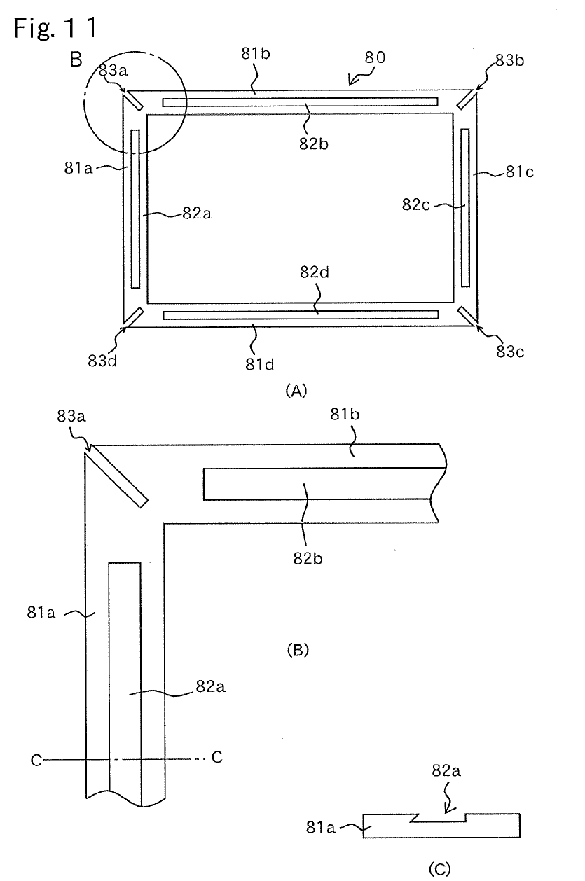

As shown in FIG. 11(A) of the overall view and FIG. 11(B) of the enlarged exploded view, the screen extending frame 80 is assembled with four frame members 81a, 81b, 81c, and 81d to be formed in a rectangular shape, and structured by fixedly joined by means of welding, or the like.

On the four frame members 81a, 81b, 81c, and 81d, engagement grooves 82a, 82b, 82c, and 82d with which engagement elements formed in a screen extending jig are engaged each are formed.

There are formed a narrow cut groove 83a in the outer side of the joint of the frame members 81a and 81b from the outer corner toward the inner corner; a narrow cut groove 83b in the outer side of the joint of the frame members 81b and 81c from the outer corner toward the inner corner; a narrow cut groove 83c in the outer side of the joint of the frame members 81c and 81d from the outer corner toward the inner corner; and a narrow cut groove 83d in the outer side of the joint of the frame members 81d and 81a from the outer corner toward the outer corner.

All of the four frame members 81a, 81b, 81c, and 81d have the same cross-sectional shape, the engagement groove 82a with which an engagement element of the screen extending jig is engaged is formed on one face of the frame member 81a as shown by the cross-section in FIG. 11(C), and the opposite face is set to be a plane in order to attach the screen thereto.

When the screen is attached to the screen extending frame 80, the engagement elements of the extending jig are engaged with the engagement grooves 82a, 82b, 82c, and 82d, and then the extending jig is extended and reduced, the screen extending frame 80 extends and reduces, and accordingly, the tensile force to the screen is adjusted.

When the screen extending frame 80 configured by combining the four frame members 81a, 81b, 81c, and 81d is pressed in the inward direction using a tool such as the screen extending jig, a clamp, a vise, or the like, the open ends of the cut grooves 83a, 83b, 83c, and 83d are reduced, and accordingly, the frame members 81a, 81b, 81c, and 81d inwardly bend, causing the screen extending frame 80 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state of not being compressed, and as the open ends of the cut grooves 83a, 83b, 83c, and 83d, are widely open, the frame members 81a, 81b, 81c, and 81d extend to the outer side to extend the screen extending frame 80, and therefore, a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

### EMBODIMENT 7

Embodiment 7 that is obtained by modifying Embodiment 6 is shown in FIG. 10. Description of the function corresponding to that of FIG. 3 or FIG. 5 is omitted. In FIG. 10, (A) is an overall view of a screen extending frame 90, (B) is an enlarged exploded view of a portion indicated by a dashed circle B in (A), and (C) is a cross-sectional view of a portion indicated by a dashed line C in (B).

As shown in FIG. 10(A) of the overall view and FIG. 10(B) of the enlarged exploded view, the screen extending frame 90 is assembled with four frame members 91a, 91b, 91c, and 91d to be formed in a rectangular shape, and structured by fixedly joined by means of welding, or the like.

On the four frame members 91a, 91b, 91c, and 91d, engagement grooves 92a, 92b, 92c, and 92d with which engagement elements formed in a screen extending jig are engaged each are formed.

There are formed a narrow inclined cut groove 93a in the outer side of the joint of the frame members 91a and 91b from the outer corner toward the inner corner; a narrow inclined cut groove 93b in the outer side of the joint of the frame members 91b and 91c from the outer corner toward the inner corner; a narrow inclined cut groove 93c in the outer side of the joint of the frame members 91c and 91d from the outer corner toward the inner corner; and a narrow inclined cut groove 93d in the outer side of the joint of the frame members 91d and 91a from the outer corner to the inner corner.

Furthermore, there are formed on the frame member 91a a narrow cut groove 94ab that is orthogonal to the outer side from the inner side at the joint with the frame member 91b and a narrow cut groove 94ad that is orthogonal to the outer side from the inner side at the joint thereof with the frame member 91d; on the frame member 91b a narrow cut groove 94ba that is orthogonal to the outer side from the inner side at the joint with the frame member 91a and a narrow cut groove 94bc that is orthogonal to the outer side from the inner side at the joint thereof with the frame member 91c; on the frame member 91c a narrow cut groove 94cb that is orthogonal to the outer side from the inner side at the joint with the frame member 91b and a narrow cut groove 94cd that is orthogonal to the outer side from the inner side at the joint thereof with the frame member 91d; and on the frame member 91d a narrow cut groove 94dc that is orthogonal to the outer side from the inner side at the joint with the frame member 91c and a narrow cut groove 94da that is orthogonal to the outer side from the inner side at the joint thereof with the frame member 91a.

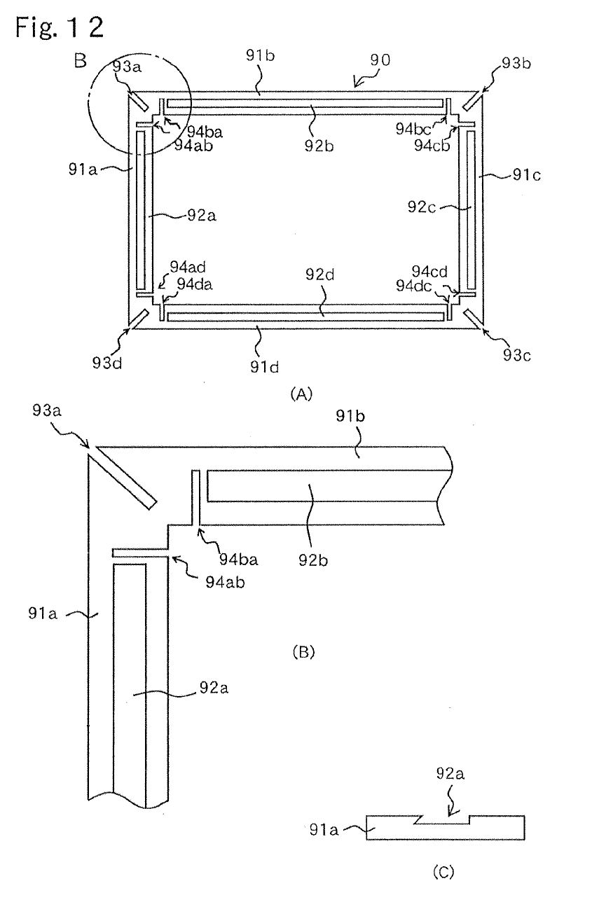

All of the four frame members 91a, 91b, 91c, and 91d have the same cross-sectional shape, the engagement groove 92a with which an engagement element of the screen extending jig is engaged is formed on one face of the frame member 91a as shown by the cross-section in FIG. 12(C), and the opposite face is set to be a plane in order to attach the screen thereto.

When the screen is attached to the screen extending frame 90, the engagement elements of the extending jig are engaged with the engagement grooves 92a, 92b, 92c, and 92d, and the extending jig is extended and reduced, the screen extending frame 90 extends and reduces, and accordingly, the tensile force to the screen is adjusted.

When the screen extending frame 90 configured by combining the four frame members 91a, 91b, 91c, and 91d is pressed in the inward direction using a tool such as the screen extending jig, a clamp, a vise, or the like, the open ends of the cut grooves 93a, 93b, 93c, and 93d that are formed in the outer side are open wide, the open ends of the cut grooves 94ab, 94ba, 94bc, 94cb, 94cd, 94dc, 94da, and 94ad that are formed in the inner side are reduced, and accordingly, the frame members 91a, 91b, 91c, and 91d inwardly bend, causing the screen extending frame 10 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state of not being compressed, and as the open ends of the cut grooves 93a, 93b, 93c, and 93d are reduced and the open ends of the cut grooves 94ab, 94ba, 94bc, 94cb, 94cd, 94dc, 94da, and 94ad are widely open, the frame members 91a, 91b, 91c, and 91d extend to extend the screen extending frame 90, and therefore, a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 93a, 93b, 93c, 93d, 94ab, 94ba, 94bc, 94cb, 94cd, 94dc, 94da, and 94ad enables protection of the open ends and supplementation of elasticity.

### EMBODIMENT 8

Embodiment 8 that is another example obtained by modifying Embodiment 6 is shown in FIG. 11.

Description of the function corresponding to that of FIG. 3 or FIG. 5 is omitted. In FIG. 11, (A) is an overall view of a screen extending frame 100, (B) is an enlarged exploded view of a portion indicated by a dashed circle B in (A), and (C) is a cross-sectional view of a portion indicated by a dashed line C in (B).

As shown in FIG. 11(A) of the overall view and FIG. 11(B) of the enlarged exploded view, the screen extending frame 100 is assembled with four frame members 101a, 101b, 101c, and 101d to be formed in a rectangular shape, and structured by fixedly joined by means of welding, or the like.

On the four frame members 101a, 101b, 101c, and 101d, engagement grooves 102a, 102b, 102c, and 102d with which engagement elements formed in a screen extending jig are engaged each are formed.

There are formed a narrow inclined cut groove 103a in the outer side of the joint of the frame members 101a and 101b from the outer corner to the inner corner; a narrow inclined cut groove 103b in the outer side of the joint of the frame members 101b and 101c from the outer corner to the inner corner; a narrow inclined cut groove 103c in the outer side of the joint of the frame members 101c and 101d from the outer corner to the inner corner; and a narrow inclined cut groove 103d in the outer side of the joint of the frame members 101d and 101a from the outer corner to the inner corner.

Furthermore, there are formed on the frame member 101a a cut groove 104ab that is orthogonal to the inner side from the outer side at the joint with the frame member 101b and a cut groove 104ad that is orthogonal to the inner side from the outer side at the joint thereof with the frame member 101d; on the frame member 101b a cut groove 104ba that is orthogonal to the inner side from the outer side at the joint with the frame member 101a and a cut groove 104bc that is orthogonal to the inner side from the outer side at the joint thereof with the frame member 101c; on the frame member 101c a cut groove 104cb that is orthogonal to the inner side from the outer side at the joint with the frame member 101b and a cut groove 104cd that is orthogonal to the inner side from the outer side at the joint thereof with the frame member 101d; and on the frame member 101d a cut groove 104dc that is orthogonal to the inner side from the outer side at the joint with the frame member 101c and a cut groove 104da that is orthogonal to the inner side from the outer side at the joint thereof with the frame member 101a.

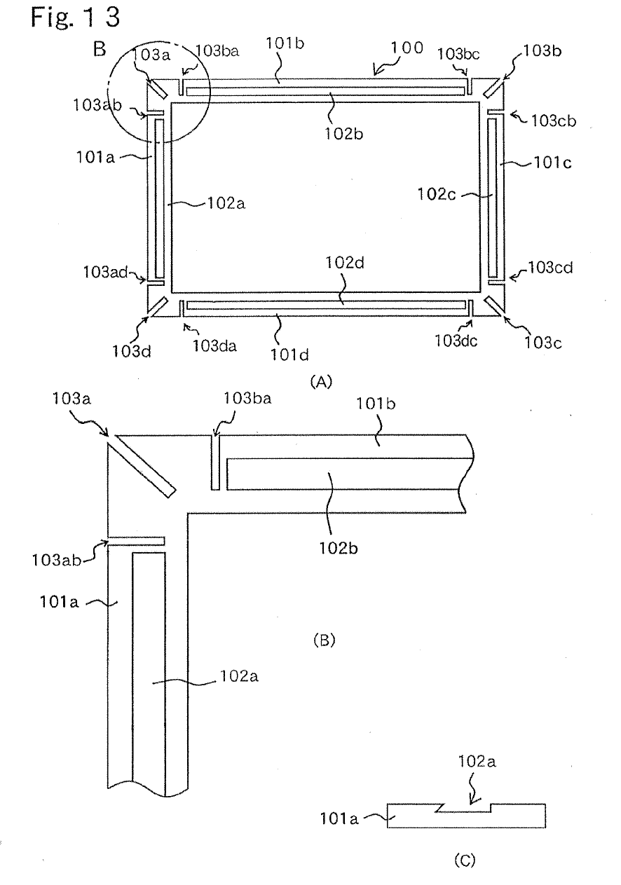

All of the four frame members 101a, 101b, 101c, and 101d have the same cross-sectional shape, the engagement groove 102a with which an engagement element of the screen extending jig is engaged is formed on one face of the frame member 101a as shown by the cross-section in FIG. 13(C), and the opposite face is set to be a plane in order to attach the screen thereto.

When the screen is attached to the screen extending frame 100, the engagement elements of the extending jig are engaged with the engagement grooves 102a, 102b, 102c, and 102d, and the extending jig is extended and reduced, the screen extending frame 100 extends and reduces, and accordingly, the tensile force to the screen is adjusted.

When the screen extending frame 100 configured by combining the four frame members 101a, 101b, 101c, and 101d is pressed in the inward direction using a tool such as the screen extending jig, a clamp, a vise, or the like, the open ends of the cut grooves 103a, 103b, 103c, and 103d are widely open, and open ends of the cut grooves 104ab, 104ba, 104bc, 104cb, 104cd, 104dc, 104da, and 104ad are reduced, and accordingly, the frame members 101a, 101b, 101c, and 101d inwardly bend, causing the screen extending frame 100 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state of not being compressed, and as the open ends of the cut grooves 103a, 103b, 103c, and 103d are reduced and the open ends of the cut grooves 104ab, 104ba, 104bc, 104cb, 104cd, 104dc, 104da, and 104ad are reduced, the frame members 101a, 101b, 101c, and 101d outwardly extend to extend the screen extending frame 100, and therefore, a tensile force is exerted on the screen attached to the screen extending frame thus extended.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 103a, 103b, 103c, 103d, 104ab, 104ba, 104bc, 104cb, 104cd, 104dc, 104da, and 104ad enables protection of the open ends and supplementation of elasticity.

### EMBODIMENT 9

Embodiment 9 that is another example obtained by modifying Embodiment 6 is shown in FIG. 12

Description of the function corresponding to that of FIG. 3 or FIG. 5 is omitted. In FIG. 12, (A) is an overall view of a screen extending frame 110, (B) is an enlarged exploded view of a portion indicated by a dashed circle B in (A), and (C) is a cross-sectional view of a portion indicated by a dashed line C in (B).

As shown in FIG. 12(A) of the overall view and FIG. 12(B) of the enlarged exploded view, the screen extending frame 110 is assembled with four frame members 111a, 111b, 111c, and 111d to be formed in a rectangular shape, and structured by fixedly joined by means of welding, or the like.

On the four frame members 111a, 111b, 111c, and 111d, engagement grooves 112a, 112b, 112c, and 112d with which engagement elements formed in a screen extending jig are engaged each are formed.

There are formed a narrow inclined cut groove 113a in the outer side of the joint of the frame members 111a and 111b from the outer corner to the inner corner; a narrow inclined cut groove 113b in the outer side of the joint of the frame members 111b and 111c from the outer corner to the inner corner; a narrow inclined cut groove 113c in the outer side of the joint of the frame members 111c and 111d from the outer corner to the inner corner; and a narrow inclined cut groove 113d in the outer side of the joint of the frame members 111d and 111a from the outer corner to the inner corner.

Furthermore, there are formed on the frame member 111a a narrow inclined cut groove 114ab that leads to the outer side from the inner side of the joint with the frame member 111b and a narrow inclined cut groove 114ad that leads to the outer side from the inner side of the joint thereof with the frame member 111d; on the frame member 111b a narrow inclined cut groove 114ba that leads to the outer side from the inner side of the joint with the frame member 111a and a narrow inclined cut groove 114bc that leads to the outer side from the inner side of the joint thereof with the frame member 111c; on the frame member 111c a narrow inclined cut groove 114cb that leads to the outer side from the inner side of the joint with the frame member 111b and a narrow inclined cut groove 114cd that leads to the outer side from the inner side of the joint thereof with the frame member 111d; and on the frame member 111d a narrow inclined cut groove 114dc that leads to the outer side from the inner side of the joint with the frame member 111c and a narrow inclined cut groove 114da that leads to the outer side from the inner side of the joint thereof with the frame member 111a.

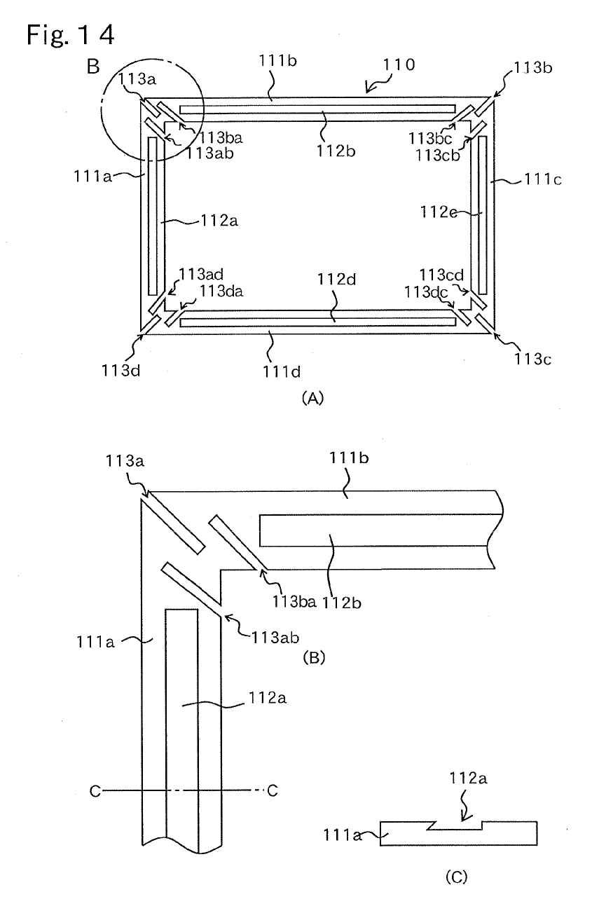

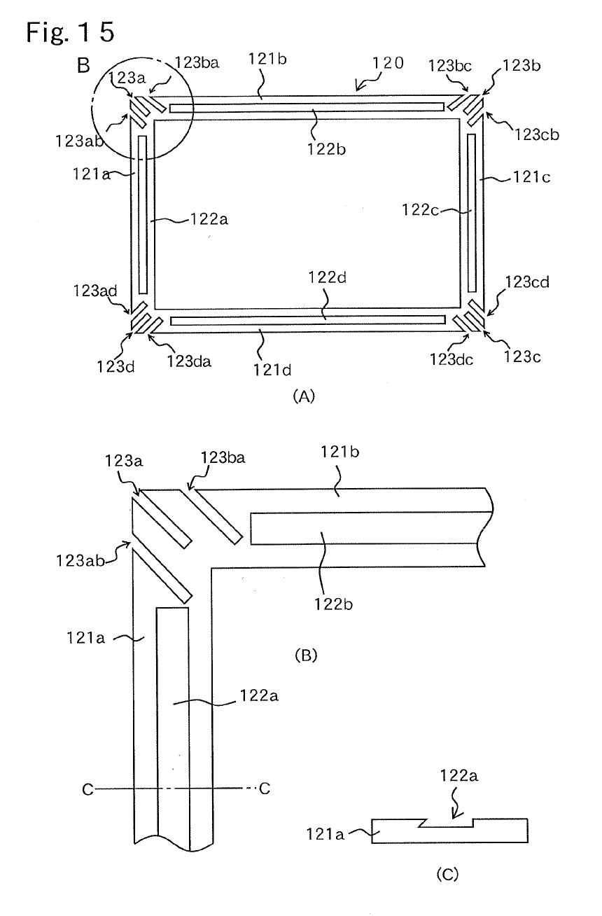

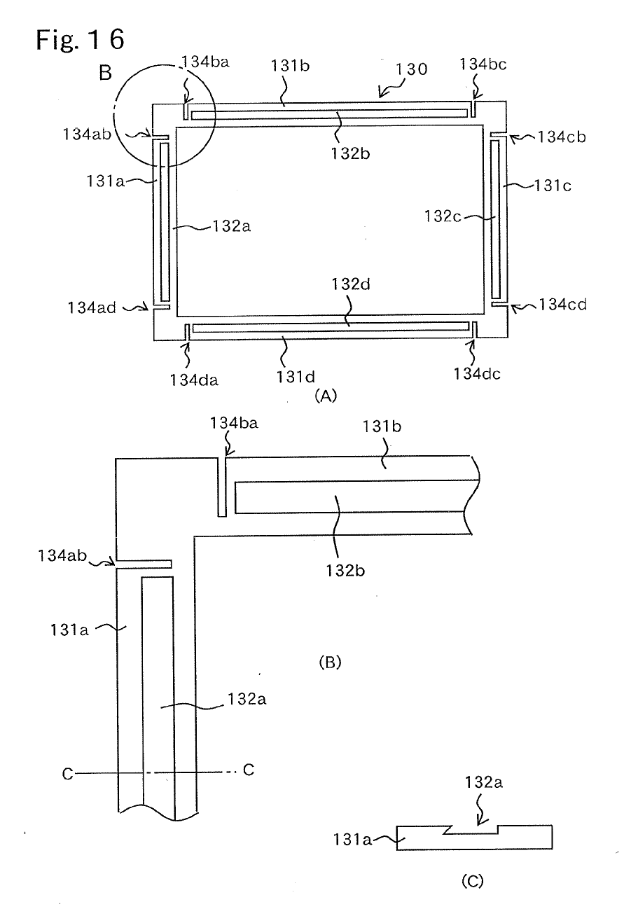

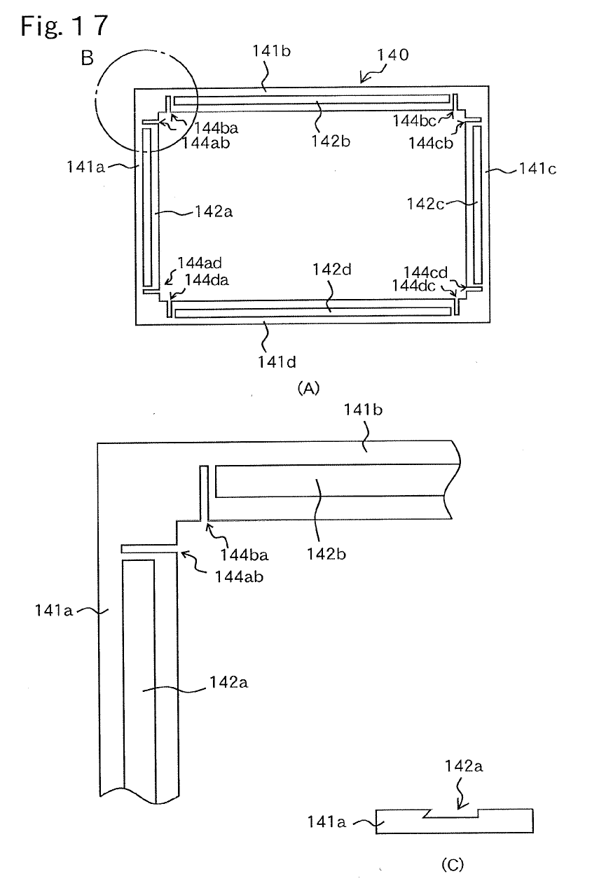

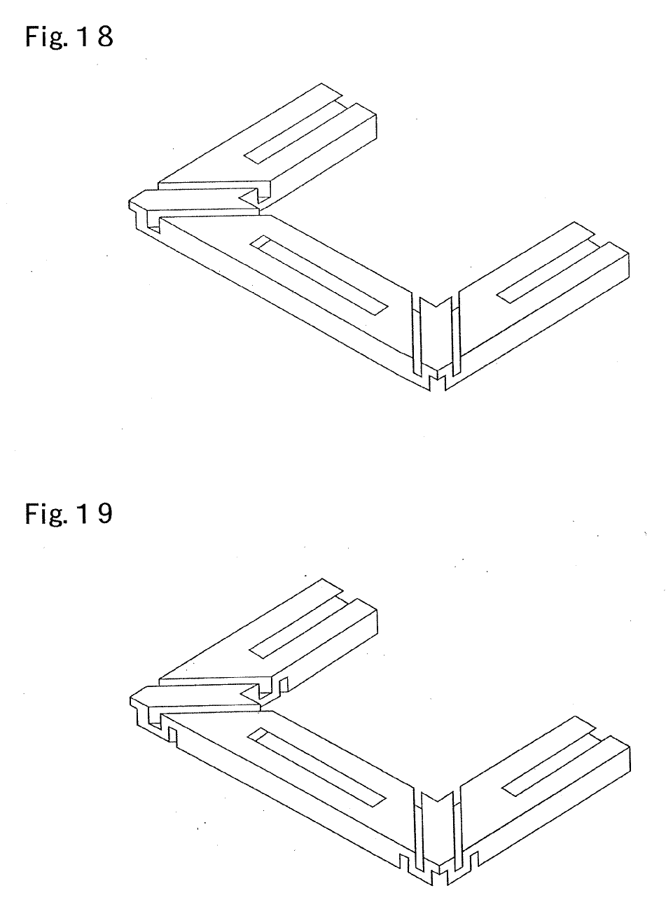

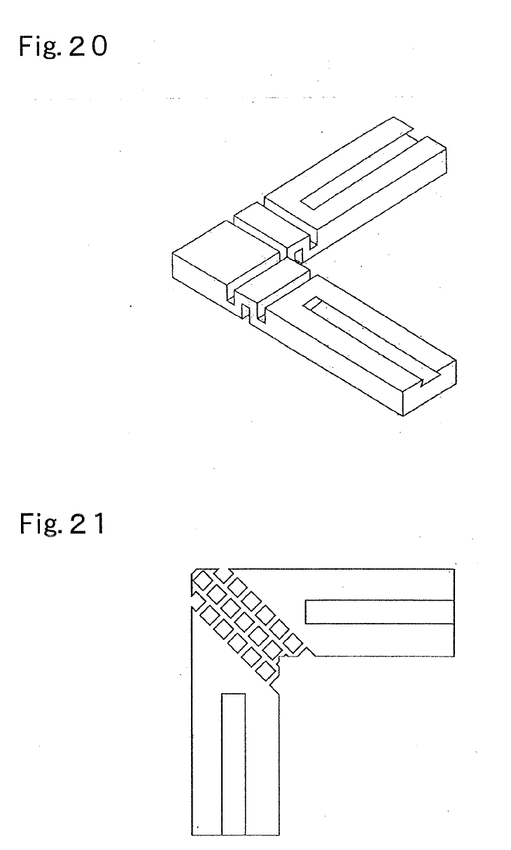

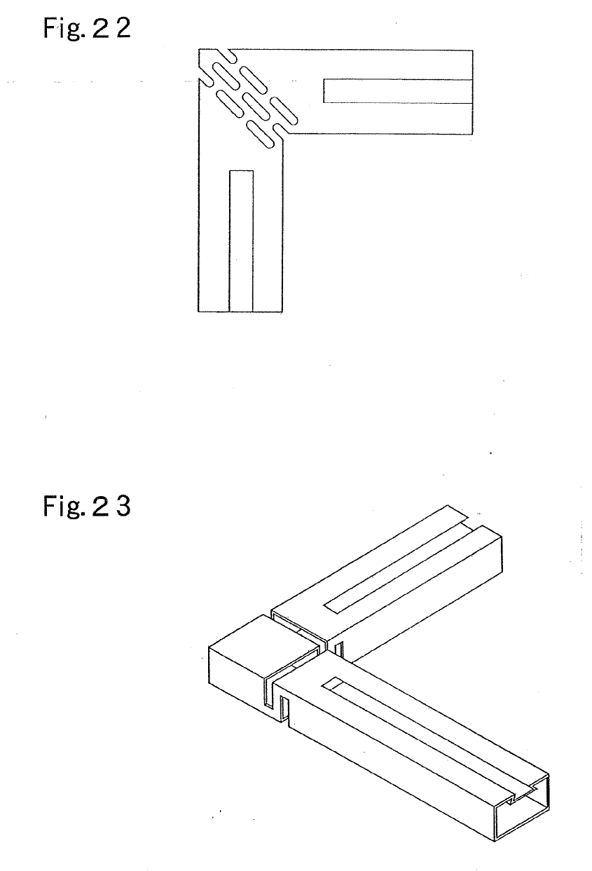

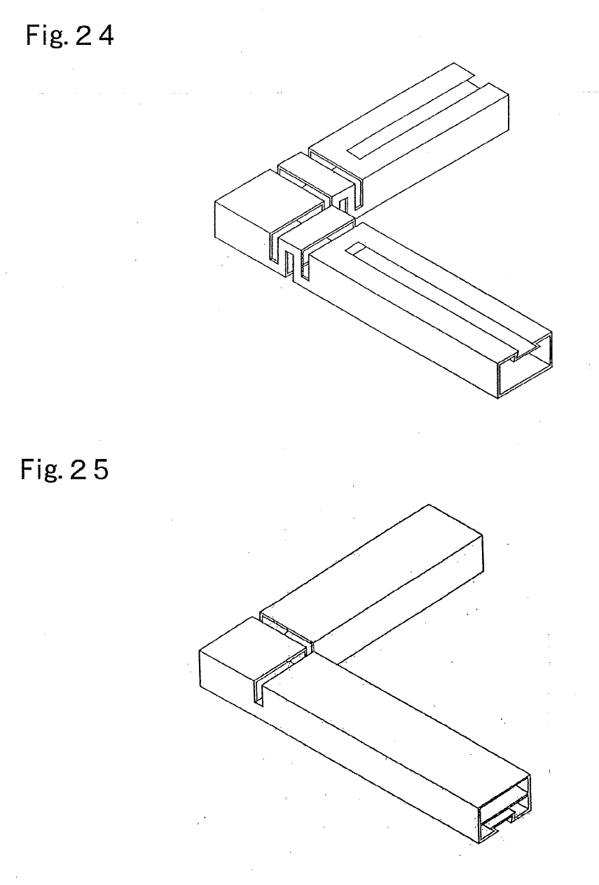

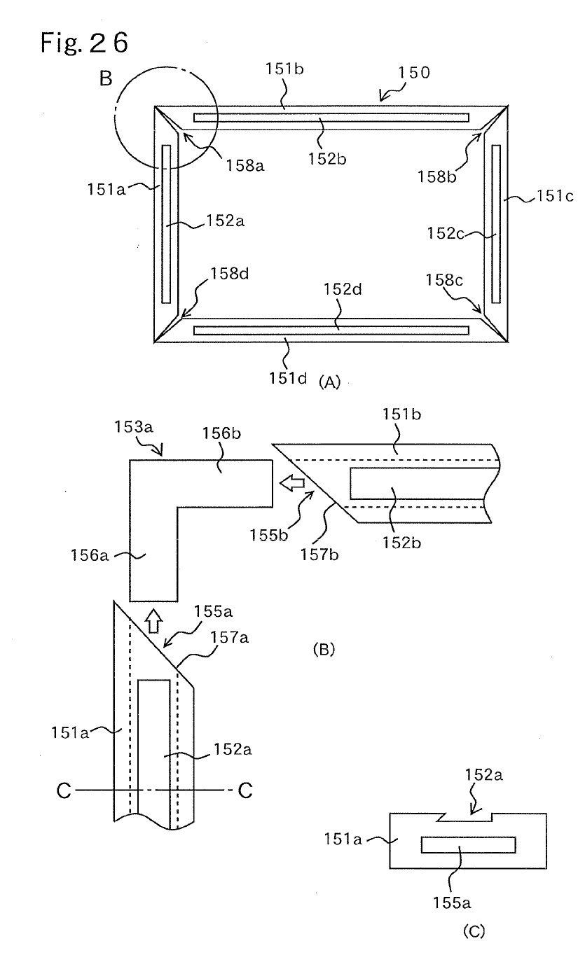

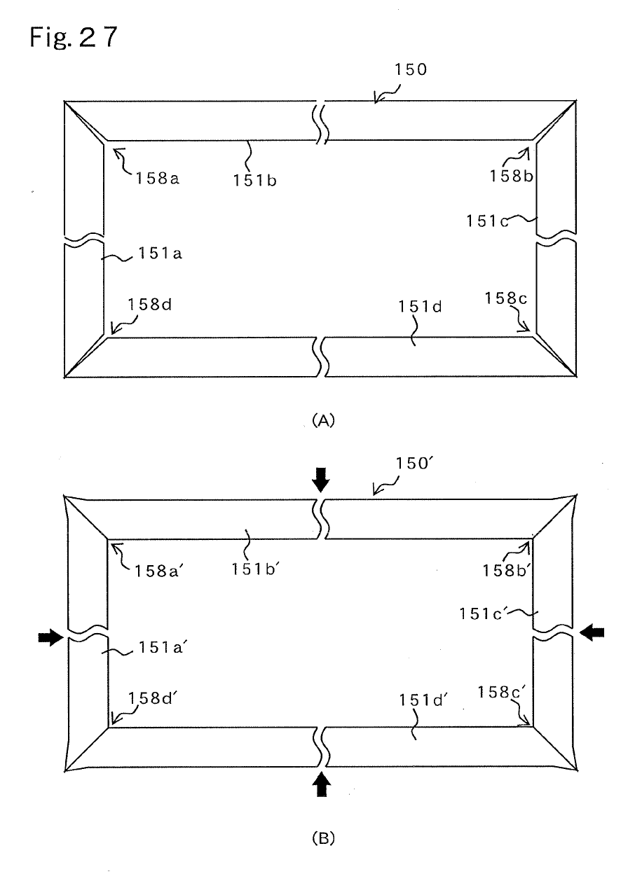

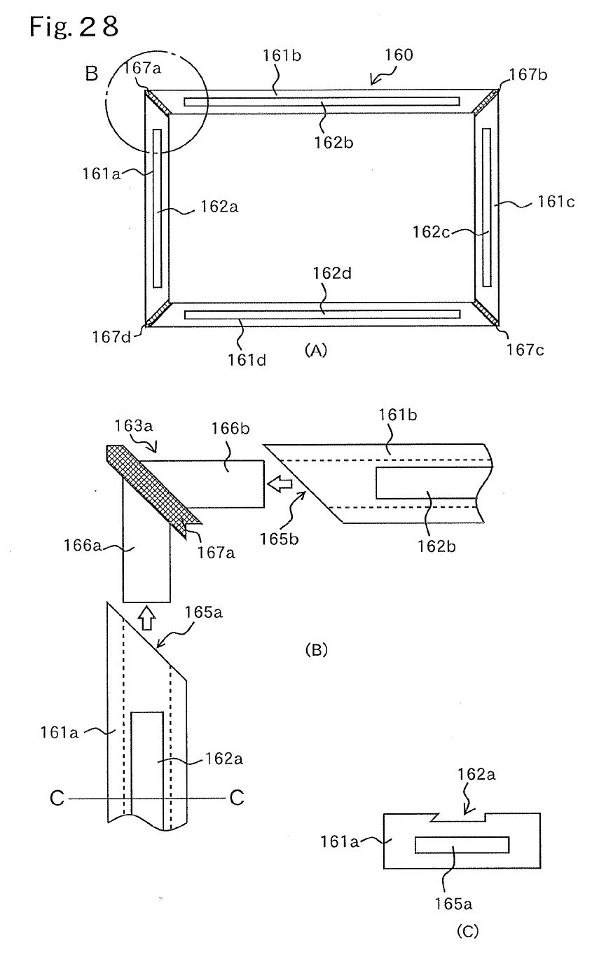

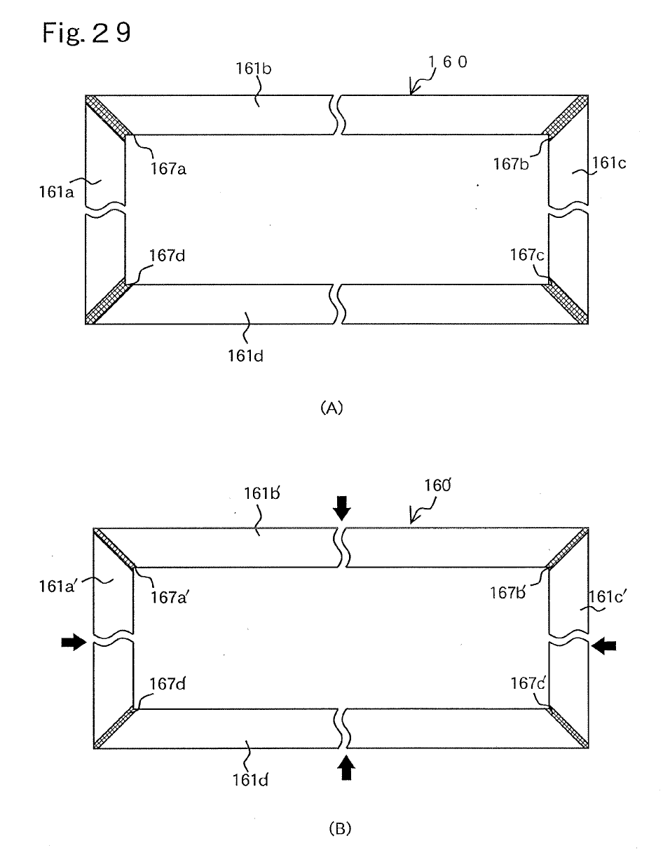

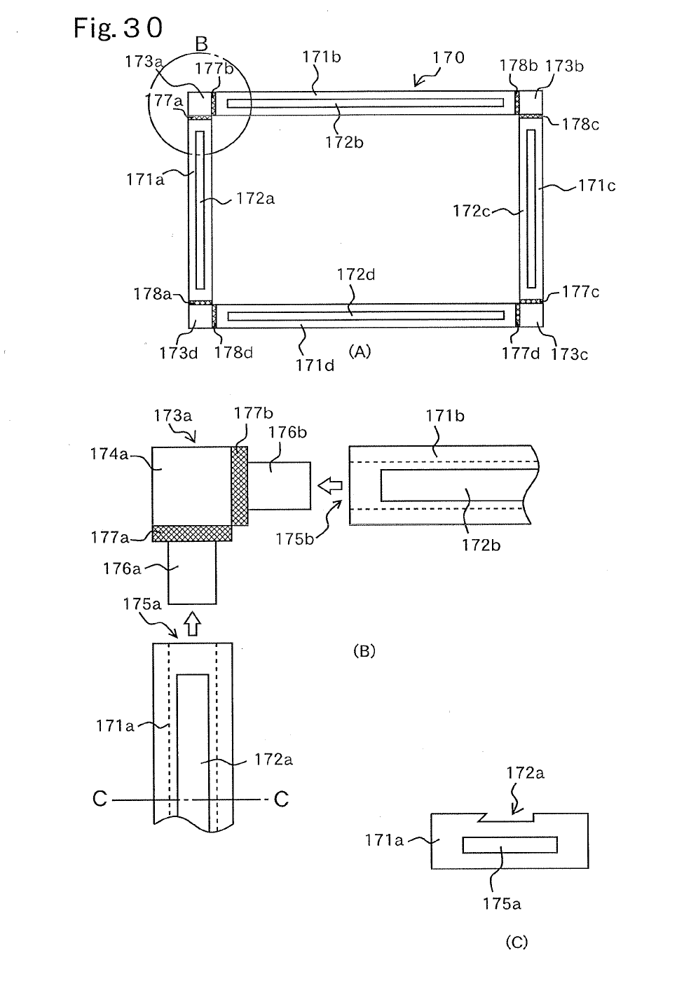

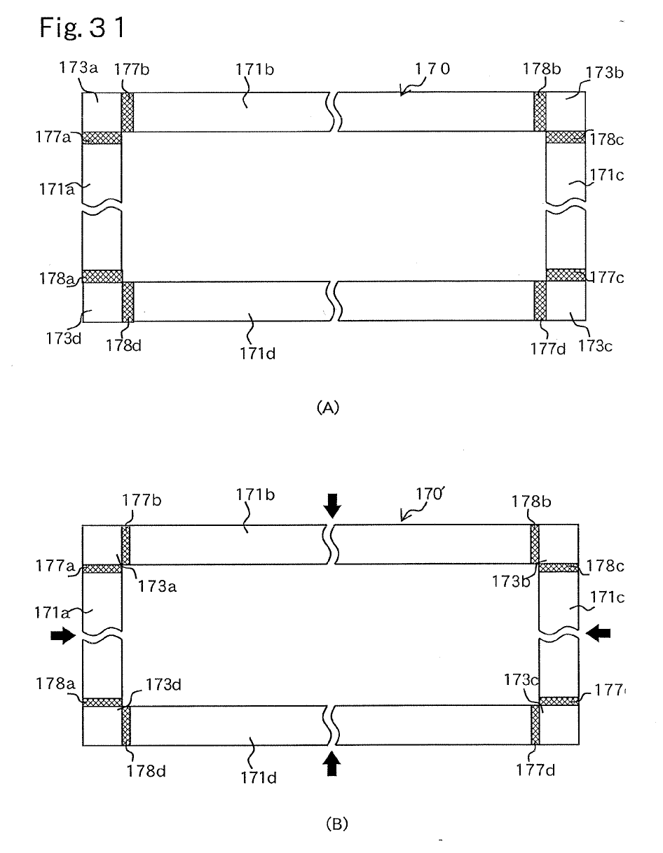

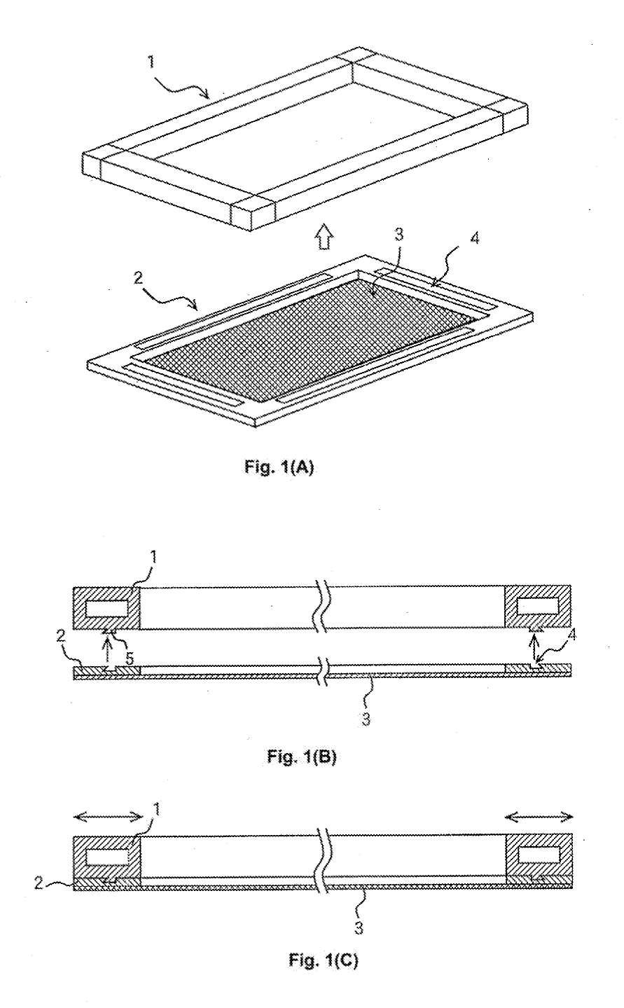

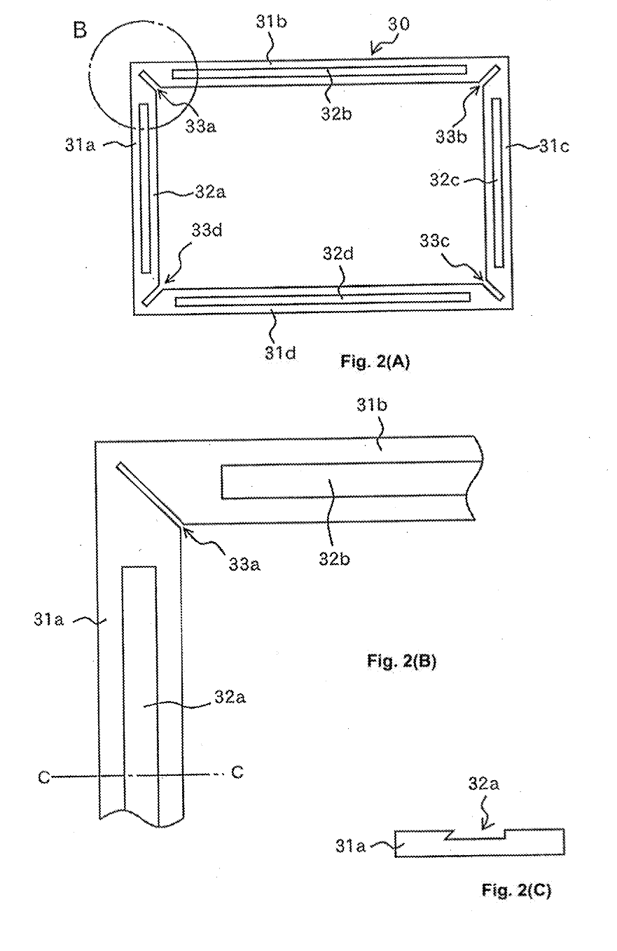

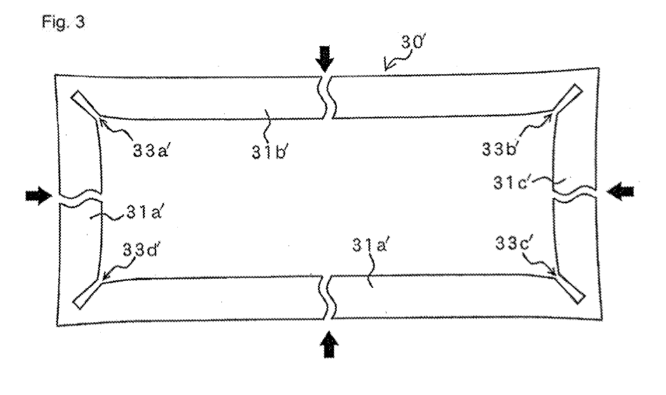

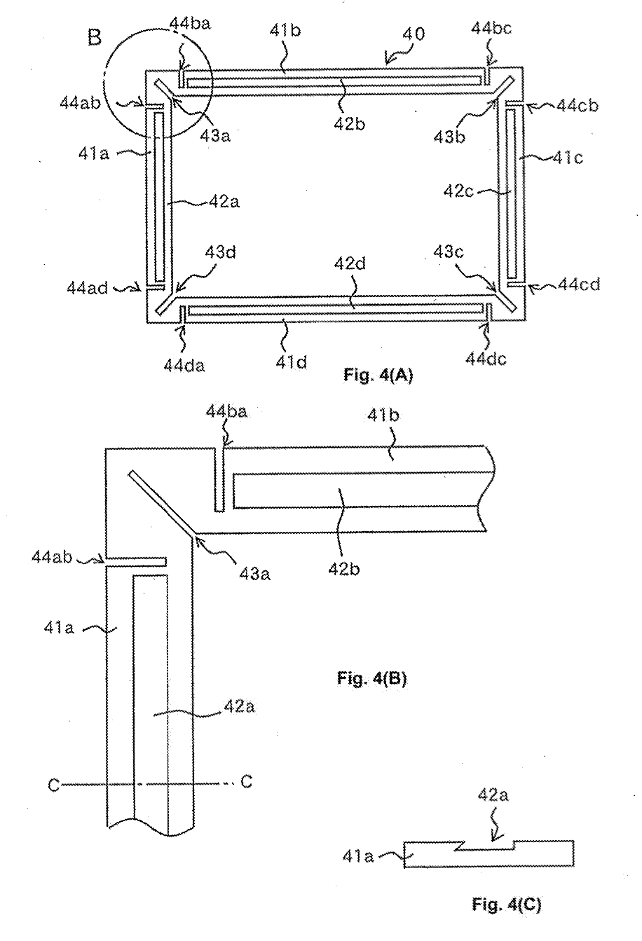

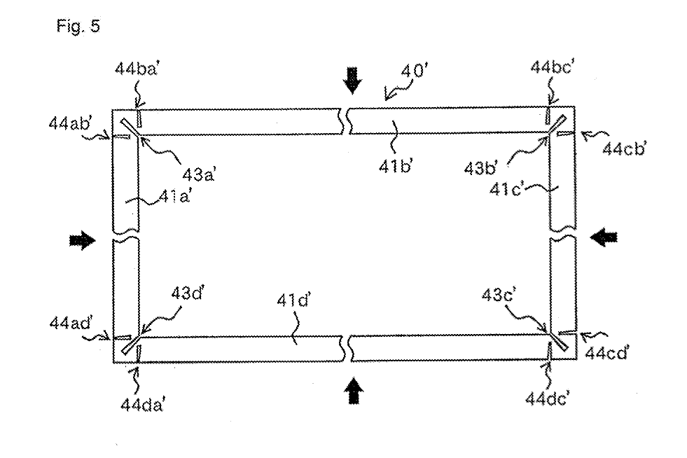

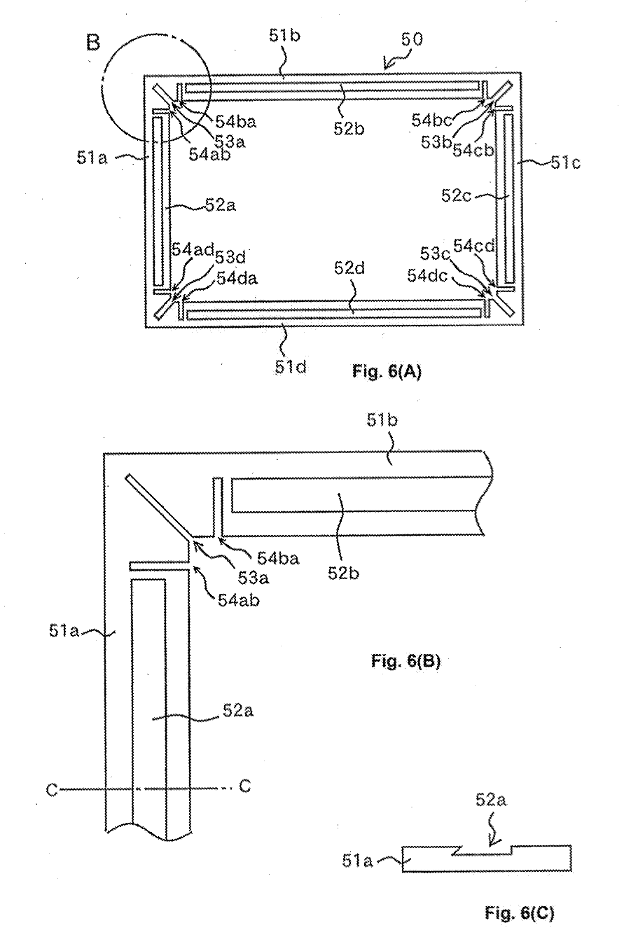

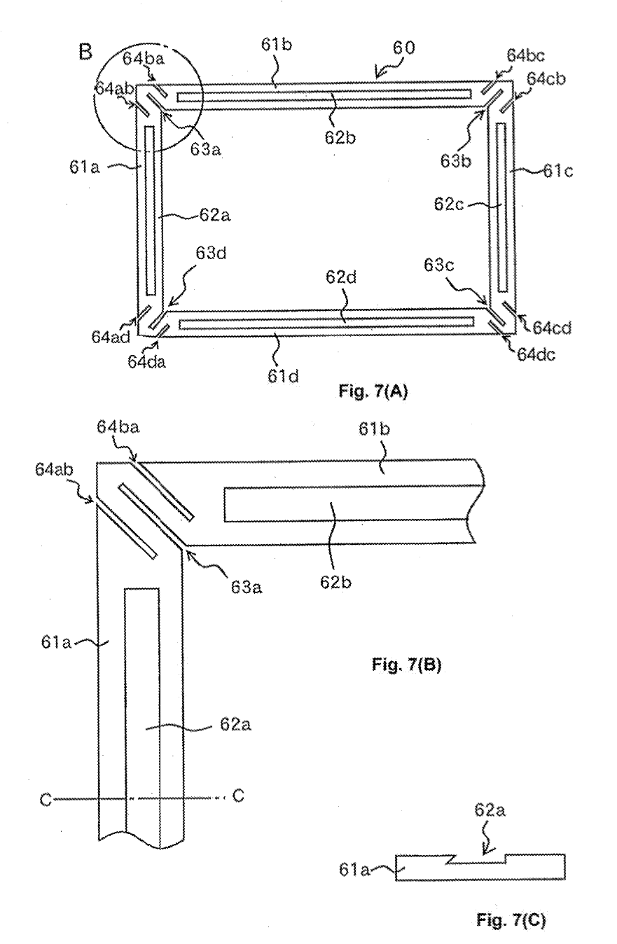

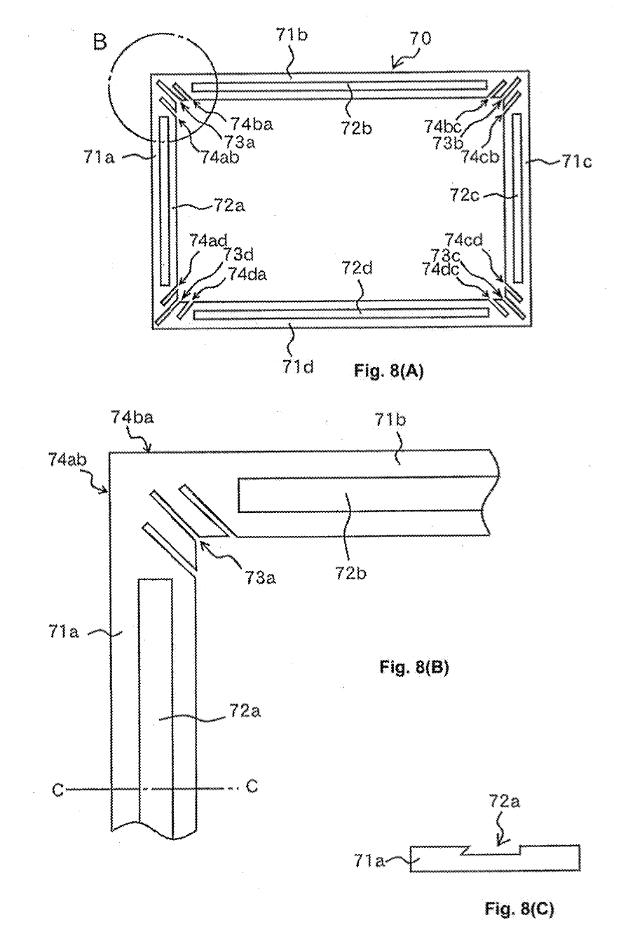

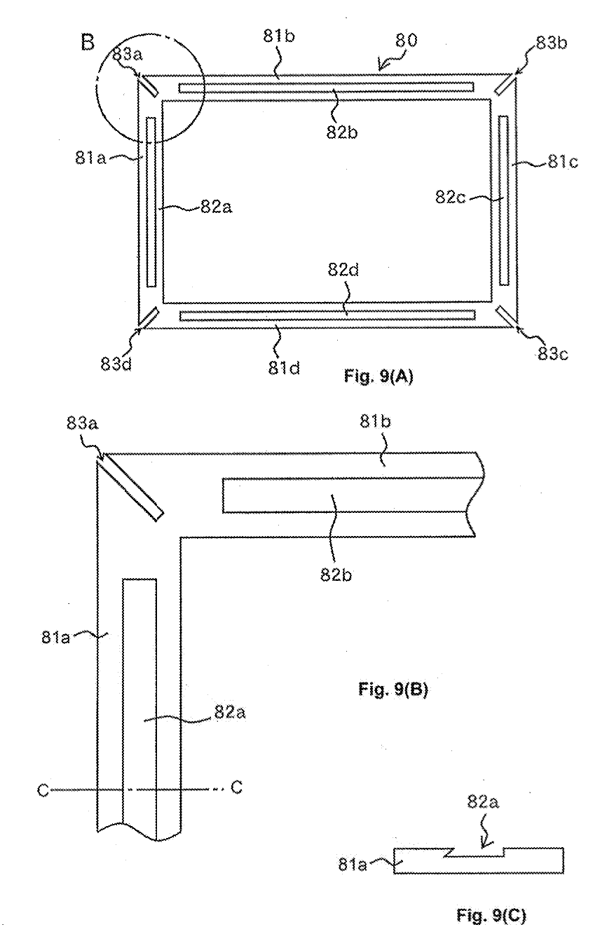

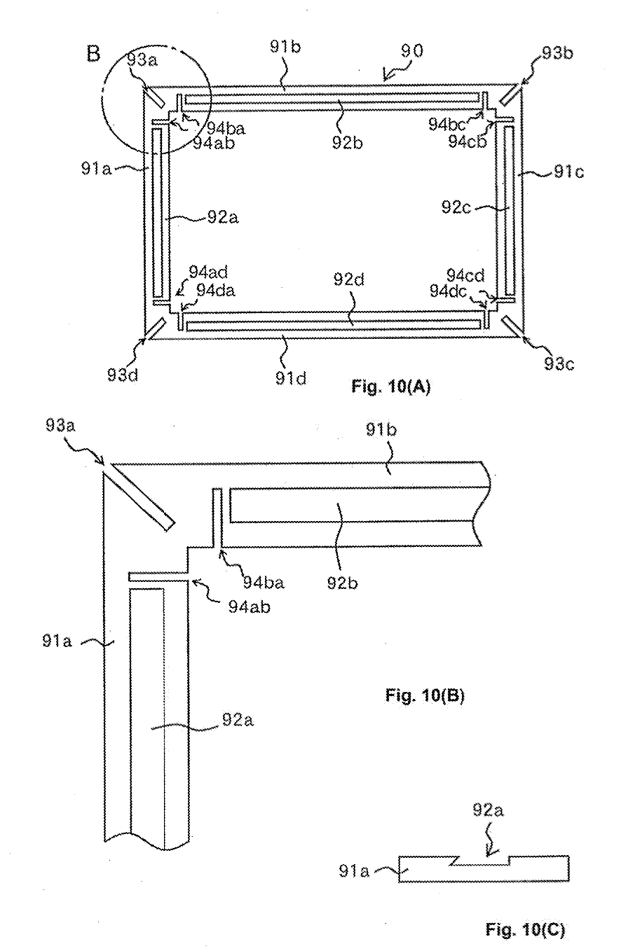

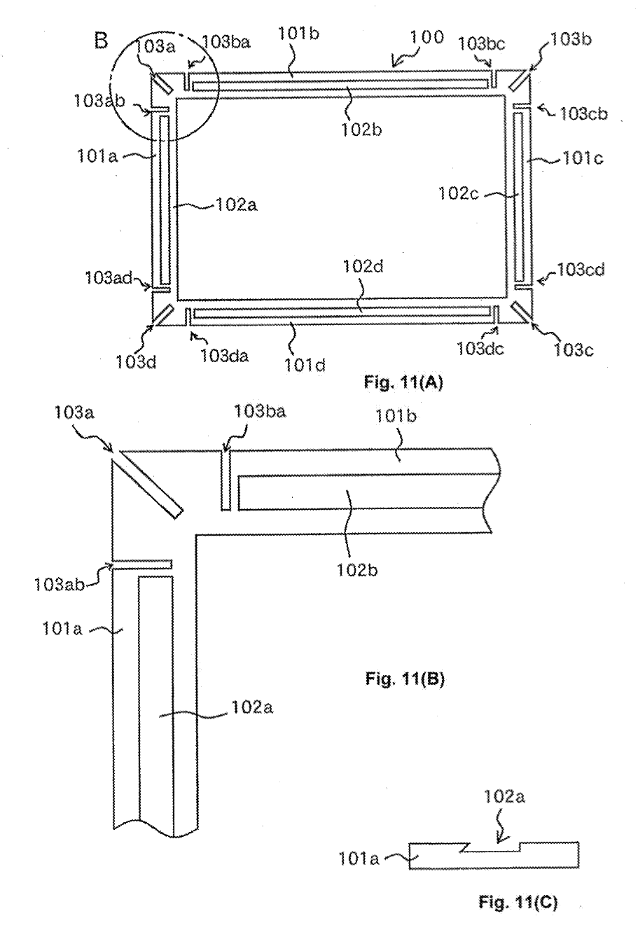

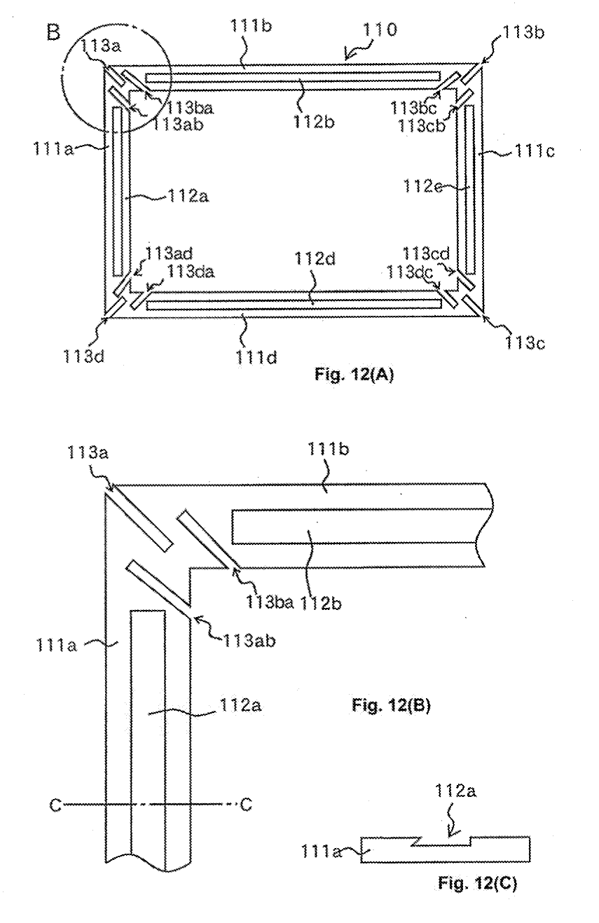

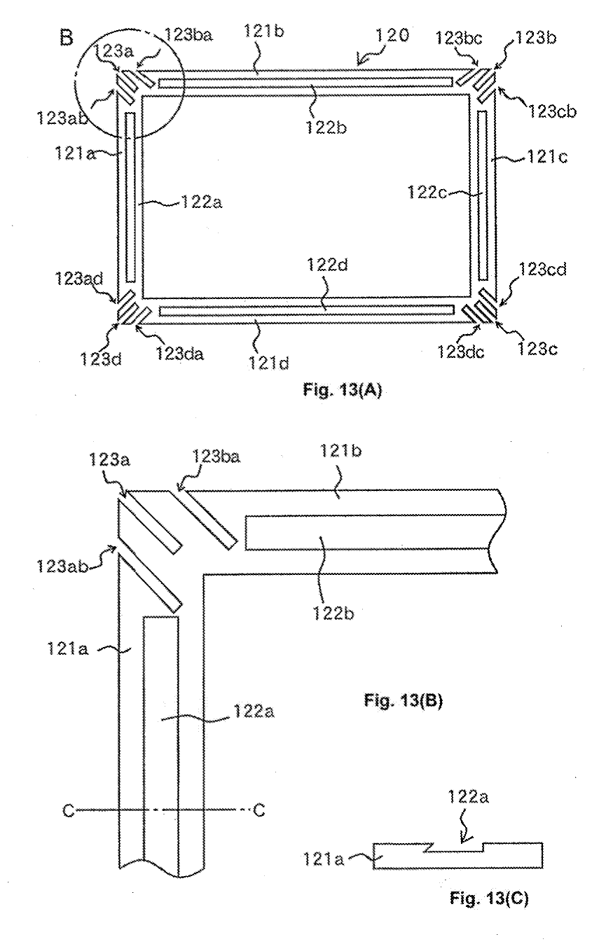

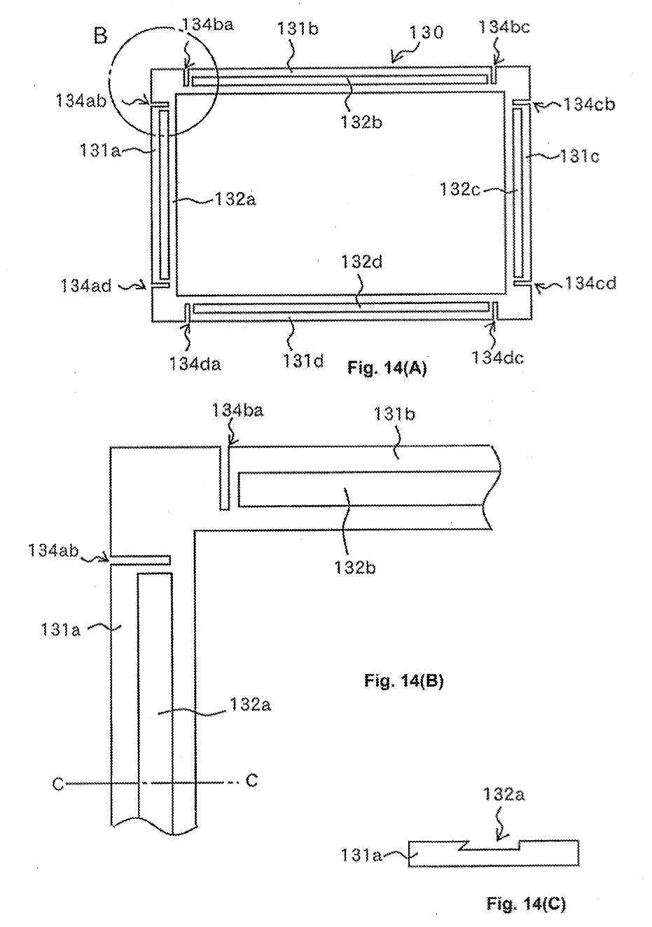

All of the four frame members 111a, 111b, 111c, and 111d have the same cross-sectional shape, the engagement groove 112a with which an engagement element of the screen extending jig is engaged is formed on one face of the frame member 111a as shown by the cross-section in FIG. 14(C), and the opposite face is set to be a plane in order to attach the screen thereto.

When the screen is attached to the screen extending frame 110, the engagement elements of the extending jig are engaged with the engagement grooves 112a, 112b, 112c, and 112d, and the extending jig is extended and reduced, the screen extending frame 110 extends and reduces, and accordingly, the tensile force to the screen is adjusted.

When the screen extending frame 110 configured by combining the four frame members 111a, 111b, 111c, and 111d is pressed in the inward direction using a tool such as the screen extending jig, a clamp, a vise, or the like, the open ends of the cut grooves 113a, 113b, 113c, and 113d that are formed in the outer side are widely open, and open ends of the cut grooves 114ab, 114ba, 114bc, 114cb, 114cd, 114dc, 114da, and 114ad that are formed in the inner side are reduced, and accordingly, the frame members 111a, 111b, 111c, and 111d inwardly bend, causing the screen extending frame 110 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 113a, 113b, 113c, and 113d that are formed in the outer side are reduced and the open ends of the cut grooves 114ab, 114ba, 114bc, 114cb, 114cd, 114dc, 114da, and 114ad that are formed in the inner side are widely open, the frame members 111a, 111b, 111c, and 111d extend outwardly to extend the screen extending frame 110, and therefore, a tensile force is exerted on the screen attached to the screen extending frame thus extended.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 113a, 113b, 113c, 113d, 114ab, 114ba, 114bc, 114cb, 114cd, 114dc, 114da, and 114ad enables protection of the open ends and supplementation of elasticity.

### EMBODIMENT 10

Embodiment 10 that is another example obtained by modifying Embodiment 6 is shown in FIG. 13.

Description of the function corresponding to that of FIG. 5 or FIG. 7 is omitted. In FIG. 13, (A) is an overall view of a screen extending frame 120, (B) is an enlarged exploded view of a portion indicated by a dashed circle B in (A), and (C) is a cross-sectional view of a portion indicated by a dashed line C in (B).

As shown in FIG. 13(A) of the overall view and FIG. 13(B) of the enlarged exploded view, the screen extending frame 120 is assembled with four frame members 121a, 121b, 121c, and 121d to be formed in a rectangular shape, and structured by fixedly joined by means of welding, or the like.

On the four frame members 121a, 121b, 121c, and 121d, engagement grooves 122a, 122b, 122c, and 122d with which engagement elements formed in a screen extending jig are engaged each are formed.

There are formed a narrow inclined cut groove 123a in the outer side of the joint of the frame members 121a and 121b from the outer corner to the inner corner; a narrow inclined cut groove 123b in the outer side of the joint of the frame members 121b and 121c from the outer corner to the inner corner; a narrow inclined cut groove 123c in the outer side of the joint of the frame members 121c and 121d from the outer corner to the inner corner; and a narrow inclined cut groove 123d in the outer side of the joint of the frame members 121d and 121a from the outer corner to the inner corner.

Furthermore, there are formed on the frame member 121a a narrow inclined cut groove 124ab that leads to the inner side from the outer side at the joint with the frame member 121b and a narrow inclined cut groove 124ad that leads to the inner side from the outer side at the joint thereof with the frame member 121d; on the frame member 121b a narrow inclined cut groove 124ba that leads to the inner side from the outer side at the joint with the frame member 121a and a narrow inclined cut groove 124bc that leads to the inner side from the outer side at the joint thereof with the frame member 121c; on the frame member 121c a narrow inclined cut groove 124cb that leads to the inner side from the outer side at the joint with the frame member 121b and a narrow inclined cut groove 124cd that leads to the inner side from the outer side at the joint thereof with the frame member 121d; and on the frame member 121d a narrow inclined cut groove 124dc that leads to the inner side from the outer side at the joint with the frame member 121c and a narrow inclined cut groove 124da that leads to the inner side from the outer side at the joint thereof with the frame member 121a.

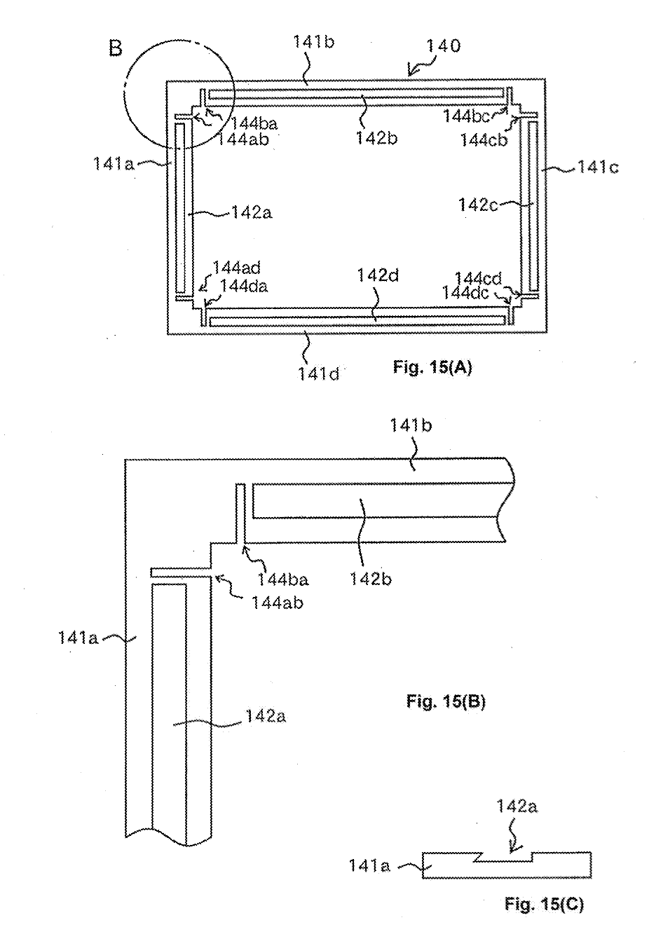

All of the four frame members 121a, 121b, 121c, and 121d have the same cross-sectional shape, the engagement groove 122a with which an engagement element of the screen extending jig is engaged is formed on one face of the frame member 121a as shown by the cross-section in FIG. 15(C), and the opposite face is set to be a plane in order to attach the screen thereto.

When the screen is attached to the screen extending frame 120, the engagement elements of the extending jig are engaged with the engagement grooves 122a, 122b, 122c, and 122d, and the extending jig is extended and reduced, the screen extending frame 120 extends and reduces, and accordingly, the tensile force to the screen is adjusted.

When the screen extending frame 120 configured by combining the four frame members 121a, 121b, 121c, and 121d is pressed in the inward direction using a tool such as the screen extending jig, a clamp, a vise, or the like, the open ends of the cut grooves 123a, 123b, 123c, 123d, 124ab, 124ba, 124bc, 124cb, 124cd, 124dc, 124da, and 124ad are widely open, and accordingly, the frame members 121a, 121b, 121c, and 121d inwardly bend, causing the screen extending frame 120 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 123a, 123b, 123c, 123d, 124ab, 124ba, 124bc, 124cb, 124cd, 124dc, 124da, and 124ad are reduced, the frame members 121a, 121b, 121c, and 121d extend outwardly to extend the screen extending frame 120, and therefore, a tensile force is exerted on the screen fixed to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 123a, 123b, 123c, 123d, 124ab, 124ba, 124bc, 124cb, 124cd, 124dc, 124da, and 124ad enables protection of the open ends and supplementation of elasticity.

### EMBODIMENT 11

Embodiment 11 is shown in FIG. 14

Description of the function corresponding to that of FIG. 3 or FIG. 5 is omitted.

In FIG. 14, (A) is an overall view of a screen extending frame 130, (B) is an enlarged exploded view of a portion indicated by a dashed circle B in (A), and (C) is a cross-sectional view of a portion indicated by a dashed line C in (B).

As shown in FIG. 14(A) of the overall view and FIG. 14(B) of the enlarged exploded view, the screen extending frame 130 is assembled with four frame members 131a, 131b, 131c, and 131d to be formed in a rectangular shape, and structured by fixedly joined by means of welding, or the like.

On the four frame members 131a, 131b, 131c, and 131d, engagement grooves 132a, 132b, 132c, and 132d with which engagement elements formed in a screen extending jig are engaged each are formed.

There are formed on the frame member 131a a narrow cut groove 134ab that leads to the inner side orthogonally from the outer side at the joint with the frame member 131b and a narrow cut groove 134ad that leads to the inner side orthogonally from the outer side at the joint thereof with the frame member 131d; on the frame member 131b a narrow cut groove 134ba that leads to the inner side orthogonally from the outer side at the joint with the frame member 131a and a narrow cut groove 134bc that leads to the inner side orthogonally from the outer side at the joint thereof with the frame member 131c; on the frame member 131c a narrow cut groove 134cb that leads to the inner side orthogonally from the outer side at the joint with the frame member 131b and a narrow cut groove 134cd that leads to the inner side orthogonally from the outer side at the joint thereof with the frame member 131d; and on the frame member 131d a narrow cut groove 134dc that leads to the inner side orthogonally from the outer side at the joint with the frame member 131c and a narrow cut groove 134da that leads to the inner side orthogonally from the outer side at the joint thereof with the frame member 131a.

All of the four frame members 131a, 131b, 131c, and 131d have the same cross-sectional shape, the engagement groove 132a with which an engagement element of the screen extending jig is engaged is formed on one face of the frame member 131a as shown by the cross-section in FIG. 16(C), and the opposite face is set to be a plane in order to attach the screen thereto.

When the screen is attached to the screen extending frame 130, the engagement elements of the extending jig are engaged with the engagement grooves 132a, 132b, 132c, and 132d, and the extending jig is extended and reduced, the screen extending frame 130 extends and reduces, and accordingly, the tensile force to the screen is adjusted.

When the screen extending frame 130 configured by combining the four frame members 131a, 131b, 131c, and 131d is pressed in the inward direction using a tool such as the screen extending jig, a clamp, a vise, or the like, the open ends of the cut grooves 134ab, 134ba, 134bc, 134cb, 134cd, 134dc, 134da, and 134ad that are formed in the outer side are reduced, and accordingly, the frame members 131a, 131b, 131c, and 131d inwardly bend, causing the screen extending frame 130 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 134ab, 134ba, 134bc, 134cb, 134cd, 134dc, 134da, and 134ad that are formed in the outer side are widely open, the frame members 131a, 131b, 131c, and 131d extend outwardly to extend the screen extending frame 110, and therefore, a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 134ab, 134ba, 134bc, 134cb, 134cd, 134dc, 134da, and 134ad enables protection of the open ends and supplementation of elasticity.

### EMBODIMENT 12

Embodiment 12 is shown in FIG. 15.

Description of the function corresponding to that of FIG. 3 or FIG. 5 is omitted.

In the drawing, (A) is an overall view of a screen extending frame 140, (B) is an enlarged exploded view of a portion indicated by a dashed circle B in (A), and (C) is a cross-sectional view of a portion indicated by a dashed line C in (B).

As shown in FIG. 15 (A) of the overall view and FIG. 15 (B) of the enlarged exploded view, the screen extending frame 140 is assembled with four frame members 141a, 141b, 141c, and 141d to be formed in a rectangular shape, and structured by fixedly joined by means of welding, or the like.

On the four frame members 141a, 141b, 141c, and 141d, engagement grooves 142a, 142b, 142c, and 142d with which engagement elements formed in a screen extending jig are engaged each are formed.

There are formed on the frame member 141a a narrow cut groove 144ab that leads to the outer side orthogonally from the inner side at the joint with the frame member 141b and a narrow cut groove 144ad that leads to the outer side orthogonally from the inner side at the joint thereof with the frame member 141d; on the frame member 141b a narrow cut groove 144ba that leads to the outer side orthogonally from the inner side at the joint with the frame member 141a and a narrow cut groove 144bc that leads to the outer side orthogonally from the inner side at the joint thereof with the frame member 141c; on the frame member 141c a narrow cut groove 144cb that leads to the outer side orthogonally from the inner side at the joint with the frame member 141b and a narrow cut groove 144cd that leads to the outer side orthogonally from the inner side at the joint thereof with the frame member 141d; and on the frame member 141d a narrow cut groove 144dc that leads to the outer side orthogonally from the inner side at the joint with the frame member 141c and a narrow cut groove 144da that leads to the outer side orthogonally from the inner side at the joint thereof with the frame member 141a.

All of the four frame members 141a, 141b, 141c, and 141d have the same cross-sectional shape, the engagement groove 142a with which an engagement element of the screen extending jig is engaged is formed on one face of the frame member 141a as shown by the cross-section in FIG. 17(C), and the opposite face is set to be a plane in order to attach the screen thereto.

When the screen is attached to the screen extending frame 140, the engagement elements of the extending jig are engaged with the engagement grooves 142a, 142b, 142c, and 142d, and the extending jig is extended and reduced, the screen extending frame 140 extends and reduces, and accordingly, the tensile force to the screen is adjusted.

When the screen extending frame 140 configured by combining the four frame members 141a, 141b, 141c, and 141d is pressed in the inward direction using a tool such as the screen extending jig, a clamp, a vise, or the like, the open ends of the cut grooves 143ab, 143ba, 143bc, 143cb, 143cd, 143dc, 143da, and 143ad that are formed in the inner side are reduced, and accordingly, the frame members 141a, 141b, 141c, and 141d inwardly bend, causing the screen extending frame 140 to be reduced.

The screen is, then, fixed to the reduced screen extending frame by means of adhesion, or the like.

In the state where fixation of the screen to the reduced screen extending frame is completed, the pressing force to the reduced screen extending frame exerted by the screen extending jig, the clamp, the vice, or the like is released.

As a result of releasing the pressing force to the reduced screen extending frame, the frame members that inwardly bend will all return to the shape of the state not being compressed, and as the open ends of the cut grooves 144ab, 144ba, 144bc, 144cb, 144cd, 144dc, 144da, and 144ad that are formed in the inner side are widely open, the frame members 141a, 141b, 141c, and 141d extend outwardly to extend the screen extending frame 140, and therefore, a tensile force is exerted on the screen attached to the extended screen extending frame.

Since the tensile force is exerted even in the state of not using the extending jig, it is possible to keep the screen to be in tension even in the state where the screen is simply fixed to the screen extending frame, and there occurs no sagging in the screen.

Insertion of a solid elastic element such as natural rubber or synthetic rubber or a non-solid spring such as a plate spring or a coil spring into the cut grooves 144ab, 144ba, 144bc, 144cb, 144cd, 144dc, 144da, and 144ad enables protection of the open ends and supplementation of elasticity. INDUSTRIAL APPLICABILITY

As understood from the above description, according to the screen extending frame of the present invention, since a tensile force is exerted on the screen thus attached thereto, even in the state of not using an extending jig, it is possible to keep the screen to be in tension even when the screen is simply fixed in the screen extending frame, and printing is possible without using the screen extending jig with no sagging in the screen.

Therefore, it is possible to safely store and transport the screen even after being taken out from a screen extending jig that is heavy, bulky, and expensive, with regard to storage and transportation. That is useful for managing the screen to be used in screen printing.

In addition, installation of a mechanism for mounting a screen extending frame on a screen printing machine and a mechanism for expanding and reducing the mounted screen extending frame makes an overall configuration of the printing machine simple.

REFERENCE NUMERALS

1 screen extending jig

2 screen extending frame

3 screen

4, 32a˜32d, 42a˜42d, 52a˜52d, 62a˜62d, 72a˜72d, 82a˜82d, 92a˜92d, 102a˜102d, 112a˜112d, 122a˜122d, 132a˜132d engaging grooves

5 engaging element

10, 20, 30, 40, 50, 60, 70, 80, 90, 100, 11-0, 120, 130, 1401 screen extending frame

11a˜11d, 21a˜21d, 31a˜31d, 41a˜41d, 51a˜51d, 61a˜61d, 71a˜71d, 81a˜81d, 91a˜91d, 101a˜101d, 111a˜111d, 121a˜121d, 131a˜131d, 141a˜141d frame members

13a, 23a˜23d, 163a, 173a˜173d, 43a corner member

33a˜33d, 43a˜43d, 53a˜53d, 63a˜63d, 73a˜73d, 83a˜83d, 93a˜93d, 103a˜103d, 123a˜123d cutting groove

1. A screen extending frame having a rectangular shape, said screen extending frame comprising:
four frame members connected so as to define a rectangular shape, each of said four frame members having a square cross sectional shape,
and said four screen frame members are connected at a plurality of joints,
and one face of each of said four frame members is attachable to a screen,
and an opposite face of each of said four frame members is adopted to a screen extending jig having an extending and reducing function,
wherein said four frame members are individual units, adjacent frame members are joined by a corner member respectively, and couplings of said four frame members and said four corner members have flexibility and elasticity.

2. The screen extending frame according to claim 1,
wherein end faces of connecting portions to which said four frame members are adjacent are faces inclined in the longitudinal direction of said four frame members, and gaps are formed between respective inclined faces.

3. The screen extending frame according to claim 1,
wherein end faces of connecting portions to which said four frame members are adjacent are faces inclined in the longitudinal direction of said four frame members, and elastic elements are provided between respective inclined faces.

4. The screen extending frame according to claim 3,
wherein said elastic element is made of natural rubber or synthetic rubber.

5. The screen extending frame according to claim 3,
wherein said elastic element is a coil spring.

6. The screen extending frame according to claim 3,
wherein said elastic element is a leaf spring.

7. The screen extending frame according to claim 1,
wherein end faces of connecting portions to which said four frame members are adjacent are faces orthogonal to the longitudinal direction of said four frame members, said corner members are rectangular parallelepiped shape, and elastic elements are provided respectively between the orthogonal faces of said frame members and said corner members.

8. The screen extending frame according to claim 7,
wherein said elastic element is made of natural rubber or synthetic rubber.

9. The screen extending frame according to claim 7,
wherein said elastic element is a coil spring.

10. The screen extending frame according to claim 7,
wherein said elastic element is a leaf spring.

11. A screen printing apparatus, having:
a mechanism for mounting a screen extending frame; and
a mechanism for extending and reducing the mounted screen extending frame.
